(19) United States
(12) Patent Application Publication
(10) Pub. No.: US 2024/0329162 A1
(43) Pub. Date: Oct. 3, 2024

(54) PROBE APPARATUS, AND MEASUREMENT METHOD AND MEASUREMENT SYSTEM OF JUNCTION RESISTANCE OF SUPERCONDUCTING QUBIT

(71) Applicant: Origin Quantum Computing Technology (Hefei) Co., Ltd, Hefei (CN)

(72) Inventors: Yongjie ZHAO, Hefei (CN); Xiansheng JIN, Hefei (CN); Yao LIU, Hefei (CN); Hui ZHANG, Hefei (CN); Fu ZHANG, Hefei (CN)

(73) Assignee: Origin Quantum Computing Technology (Hefei) Co., Ltd, Hefei (CN)

(21) Appl. No.: 18/736,284

(22) Filed: Jun. 6, 2024

Related U.S. Application Data
(63) Continuation of application No. PCT/CN2022/138437, filed on Dec. 12, 2022.

(30) Foreign Application Priority Data
Dec. 13, 2021 (CN) 202111519238.1
Jan. 29, 2022 (CN) 202210113454.4
May 27, 2022 (CN) 202210587141.2
May 27, 2022 (CN) 202210587143.1
May 27, 2022 (CN) 202210587157.3
May 27, 2022 (CN) 202210587177.0
May 27, 2022 (CN) 202210587191.0
May 27, 2022 (CN) 202210590023.7
May 27, 2022 (CN) 202210590067.X

(51) Int. Cl. G01R 33/035; H10N 60/12; H10N 60/80

(52) U.S. Cl. CPC G01R 33/0354; H10N 60/12; H10N 60/805

(57) ABSTRACT

Disclosed are a probe apparatus, and a measurement method and a measurement system of a junction resistance of a superconducting qubit. The probe apparatus is configured to measure a superconducting quantum chip, and includes a probe set, a probe control mechanism, and a power supply module; the probe set includes two probes that are independent; the probe control mechanism is configured to control the probe set to be connected to an oxide layer on a surface of an electrode of a Josephson junction on the superconducting quantum chip; and the power supply module is configured to apply an electrical breakdown signal to two probes, to break down the oxide layer, so that the probe set forms a conductive connection with the electrode of the Josephson junction.

### CROSS-REFERENCE TO RELATED APPLICATIONS

The present application is a continuation of International Application No. PCT/CN2022/138437, filed on Dec. 12, 2022, which claims priorities to Chinese Patent Application No. 202111519238.1, filed on Dec. 13, 2021, and entitled “PROBE APPARATUS, AND MEASUREMENT SYSTEM AND METHOD OF RESISTANCE OF SUPERCONDUCTING QUANTUM CHIP”; to Chinese Patent Application No. 202210113454.4, filed on Jan. 29, 2022, and entitled “MEASUREMENT METHOD AND MEASUREMENT SYSTEM OF JUNCTION RESISTANCE OF QUBIT”; to Chinese Patent Application No. 202210587143.1, filed on May 27, 2022, and entitled “PROBE APPARATUS, AND MEASUREMENT APPARATUS, SYSTEM, AND METHOD OF JUNCTION RESISTANCE OF SUPERCONDUCTING QUBIT”; to Chinese Patent Application No. 202210587191.0, filed on May 27, 2022, and entitled “MEASUREMENT METHOD AND MEASUREMENT SYSTEM OF JUNCTION RESISTANCE OF SUPERCONDUCTING QUBIT”; to Chinese Patent Application No. 202210590067.X, filed on May 27, 2022, and entitled “MEASUREMENT METHOD AND SYSTEM OF JUNCTION RESISTANCE OF SUPERCONDUCTING QUBIT”; to Chinese Patent Application No. 202210587141.2, filed on May 27, 2022, and entitled “PROBE APPARATUS, AND MEASUREMENT SYSTEM, CIRCUIT, AND METHOD OF JUNCTION RESISTANCE OF SUPERCONDUCTING QUBIT”; to Chinese Patent Application No. 202210590023.7, filed on May 27, 2022, and entitled “ELECTRICAL CONTACT CONNECTION METHOD AND SYSTEM”; to Chinese Patent Application No. 202210587177.0, filed on May 27, 2022, and entitled “ELECTRICAL CONTACT CONNECTION METHOD AND SYSTEM”; and to Chinese Patent Application No. 202210587157.3, filed on May 27, 2022, and entitled “PROBE APPARATUS, AND MEASUREMENT SYSTEM AND METHOD OF JUNCTION RESISTANCE OF SUPERCONDUCTING QUBIT”. The disclosures of the aforementioned applications are hereby incorporated by reference in their entireties.

### TECHNICAL FIELD

The present application pertains to the field of quantum information, especially the field of quantum chip detection, and in particular, to a probe apparatus, and a measurement method and a measurement system of a junction resistance of a superconducting qubit.

### BACKGROUND

A key structure of a superconducting quantum chip is a superconducting qubit, and a key structure of the superconducting qubit is a Josephson junction. The Josephson junction is a special device formed by sandwiching a thin layer of an insulator between two electrodes. To ensure performance of the superconducting quantum chip, frequency parameters of the superconducting qubit must be strictly controlled. A representation of a normal-temperature resistance of the superconducting qubit is important information about the frequency parameters, and a resistance of the Josephson junction is the key to the representation of the normal-temperature resistance of the superconducting qubit. Therefore, the resistance of the Josephson junction needs to be accurately measured.

Currently, there is no resistance measurement solution specifically for the superconducting quantum chip. At present, resistance measurement for the superconducting quantum chip uses a resistance measurement solution of a conventional semiconductor chip. That is, a resistance is measured in a manner in which a probe is inserted into an internal structure of a device to form direct contact. This is mainly because an oxide layer is formed on an electrode of the Josephson junction. The oxide layer is not expected to be generated, but is difficult to be removed. Therefore, it is necessary to penetrate through the oxide layer to obtain a resistance between electrodes. Otherwise, presence of the oxide layer may cause interference to a measurement result. However, when the oxide layer is penetrated to obtain the resistance between the electrodes, accuracy and validity of measuring and controlling a junction resistance of the Josephson junction cannot be ensured due to a plurality of uncertainties. Therefore, the resistance measurement solution of the conventional semiconductor chip is not applicable to the superconducting quantum chip.

### SUMMARY

An objective of the present application is to provide at least one of a probe apparatus, and a measurement method and a measurement system of a junction resistance of a superconducting qubit, to resolve the problem in the prior art.

An example 1 provided in the present application: a probe apparatus, configured to measure a superconducting quantum chip, and including a probe set, a probe control mechanism, and a power supply module, where
the probe set includes two probes that are independent;
the probe control mechanism is configured to control the probe set to be connected to an oxide layer on a surface of an electrode of a Josephson junction on the superconducting quantum chip; and
the power supply module is configured to apply an electrical breakdown signal to the two probes, to break down the oxide layer, so that the probe set forms a conductive connection with the electrode of the Josephson junction.

An example 2 provided in the present application, including the example 1, where the probe set connecting to the oxide layer includes: the probe is in contact with a surface that is of the oxide layer and that is away from the electrode; or
the probe is inserted into the oxide layer, and a depth of which the probe is inserted into the oxide layer is less than or equal to a thickness of the oxide layer.

An example 3 provided in the present application, including the example 2, where the probe set connecting to the oxide layer specifically includes: the two probes are all inserted into the oxide layer on the surface of the electrode on one side of the Josephson junction, and the depth of which the probe is inserted into the oxide layer is less than or equal to the thickness of the oxide layer; or one of the two probes is inserted into the oxide layer on the surface of the electrode on one side of the Josephson junction, and an insertion depth is equal to the thickness of the oxide layer, and the other probe is in contact with the surface that is of the oxide layer and that is away from the electrode.

An example 4 provided in the present application, including the example 1, where the probe control mechanism includes displacement adjustment components, and a quantity of the displacement adjustment components is the same as a quantity of the probes; and
the displacement adjustment components are respectively connected to the probes, and configured to control the probes to be displaced in a multi-degree-of-freedom direction and to be inserted downward the Josephson junction.

An example 5 provided in the present application, including the example 1, where the probe control mechanism includes a micro force sensor, the micro force sensor is connected to the probes in the probe set, and the micro force sensor is configured to detect an insertion downward force of the probe set.

An example 6 provided in the present application, including the example 1, where a tip diameter of each of the probes ranges from 100 nm to 500 nm.

An example 7 provided in the present application, including the example 1, where a voltage of the electrical breakdown signal ranges from 0.5 V to 5 V, and a current of the electrical breakdown signal is less than or equal to 10 μA.

An example 8 provided in the present application, including the examples 1 to 7, where the probe set includes a first probe set and a second probe set.

An example 9 provided in the present application, including the example 8, where the probe control mechanism is configured to control: two probes of the first probe set to be inserted downward one side of the Josephson junction, and two probes of the second probe set to be inserted downward the other side of the Josephson junction, so that the two probe sets are respectively connected to oxide layers on surfaces of electrodes on the two sides of the Josephson junction; and
the power supply module is configured to apply the electrical breakdown signal between the probes in the first probe set and between the probes in the second probe set, to break down the oxide layers on the two sides of the Josephson junction.

An example 10 provided in the present application: a measurement method of a junction resistance of a superconducting qubit, where the superconducting qubit includes a Josephson junction, the Josephson junction includes a first electrode and a second electrode, and the measurement method includes:
electrically breaking down a first oxide layer formed on a surface of the first electrode;
electrically breaking down a second oxide layer formed on a surface of the second electrode;
applying a test current through a broken-down first oxide layer, the Josephson junction, and a broken-down second oxide layer, and measuring a voltage between the broken-down first oxide layer and the broken-down second oxide layer; and
determining the junction resistance of the superconducting qubit based on the voltage and the test current.

An example 11 provided in the present application, including the example 10, where the step of electrically breaking down a first oxide layer formed on a surface of the first electrode includes:
connecting a first probe and a second probe to the first oxide layer; and
forming a potential difference between the first probe and the second probe by applying a first breakdown voltage, to break down the first oxide layer; and
the step of electrically breaking down a second oxide layer formed on a surface of the second electrode includes:
connecting a third probe and a fourth probe to the second oxide layer; and
forming a potential difference between the third probe and the fourth probe by applying a second breakdown voltage, to break down the second oxide layer.

An example 12 provided in the present application, including the example 11, where at the same time when the potential difference is formed between the first probe and the second probe by applying the first breakdown voltage, to break down the first oxide layer, the method further includes:
applying a first protection voltage to the second electrode; and
at the same time when the potential difference is formed between the third probe and the fourth probe by applying the second breakdown voltage, to break down the second oxide layer, the method further includes:
applying a second protection voltage to the first electrode.

An example 13 provided in the present application, including the example 12, where a potential difference between the first protection voltage and the first breakdown voltage is less than a barrier voltage of a barrier layer of the Josephson junction; and
a potential difference between the second protection voltage and the second breakdown voltage is less than the barrier voltage of the barrier layer of the Josephson junction.

An example 14 provided in the present application, including the example 11, where the connecting a first probe and a second probe to the first oxide layer includes: inserting the first probe and the second probe into the first oxide layer, where an insertion depth is less than a thickness of the first oxide layer; and
the connecting a third probe and a fourth probe to the second oxide layer includes: inserting the third probe and the fourth probe into the second oxide layer, where an insertion depth is less than a thickness of the second oxide layer.

An example 15 provided in the present application, including the example 11, where the connecting a first probe and a second probe to the first oxide layer includes: inserting one of the first probe and the second probe into the first oxide layer, and enabling the other of the first probe and the second probe to be in contact with a surface that is of the first oxide layer and that is away from the first electrode; and
the connecting a third probe and a fourth probe to the second oxide layer includes: inserting one of the third probe and the fourth probe into the second oxide layer, and enabling the other of the third probe and the fourth probe to be in contact with a surface that is of the second oxide layer and that is away from the second electrode.

An example 16 provided in the present application, including the example 15, where an insertion depth of the one of the first probe and the second probe is a thickness of the first oxide layer; and
an insertion depth of the one of the third probe and the fourth probe is a thickness of the second oxide layer.

An example 17 provided in the present application, including the example 15, where a material hardness of the probe inserted into the first oxide layer is greater than a hardness of the first oxide layer; and
a material hardness of the probe inserted into the second oxide layer is greater than a hardness of the second oxide layer.

An example 18 provided in the present application, including the example 15, where a material hardness of the probe in contact with the surface that is of the first oxide layer and that is away from the first electrode is less than a hardness of the first oxide layer; and
a material hardness of the probe in contact with the surface that is of the second oxide layer and that is away from the second electrode is less than a hardness of the second oxide layer.

An example 19 provided in the present application, including the example 11, where the step of electrically breaking down a second oxide layer formed on a surface of the second electrode includes:
moving the first probe to connect the first probe and a third probe to the second oxide layer; and
forming a potential difference between the first probe and the third probe to break down the second oxide layer.

An example 20 provided in the present application, including the example 10, where the step of electrically breaking down a first oxide layer formed on a surface of the first electrode includes:
enabling one of a first probe and a second probe to be in contact with a surface that is of the first oxide layer and that is away from the first electrode; and based on pressure monitoring or resistance monitoring, inserting the other of the first probe and the second probe into the first oxide layer and enabling the other to be in contact with the first electrode; and
forming a potential difference between the first probe and the second probe by applying a first breakdown voltage, to break down the first oxide layer; and
the step of electrically breaking down a second oxide layer formed on a surface of the second electrode includes:
enabling one of a third probe and a fourth probe to be in contact with a surface that is of the second oxide layer and that is away from the second electrode; and based on pressure monitoring or resistance monitoring, inserting the other of the third probe and the fourth probe into the second oxide layer and enabling the other to be in contact with the second electrode; and
forming a potential difference between the third probe and the fourth probe by applying a second breakdown voltage, to break down the second oxide layer.

An example 21 provided in the present application, including the example 20, where the step of based on pressure monitoring, inserting the other of the first probe and the second probe into the first oxide layer and enabling the other to be in contact with the first electrode includes:
moving the other of the first probe and the second probe toward the first oxide layer on the surface of the first electrode, and monitoring, in real time, a pressure exerted on the other of the first probe and the second probe;
monitoring a first sudden change of the pressure, and continuing to move the other of the first probe and the second probe; and
monitoring a second sudden change of the pressure, and stopping movement of the other of the first probe and the second probe when the second sudden change occurs, where the other of the first probe and the second probe is in contact with and electrically connected to the surface of the first electrode at this time; and
the based on pressure monitoring, inserting the other of the third probe and the fourth probe into the second oxide layer and enabling the other to be in contact with the second electrode includes:
moving the other of the third probe and the fourth probe toward the second oxide layer on the surface of the second electrode, and monitoring, in real time, a pressure exerted on the other of the third probe and the fourth probe;
monitoring a first sudden change of the pressure, and continuing to move the other of the third probe and the fourth probe; and
monitoring a second sudden change of the pressure, and stopping movement of the other of the third probe and the fourth probe when the second sudden change occurs, where the other of the third probe and the fourth probe is in contact with and electrically connected to the surface of the second electrode at this time.

An example 22 provided in the present application, including the example 21, where the first sudden change is that a pressure changes from 0 to 0.1-10 μN, and a pressure of the second sudden change is 10 to 100 times the pressure of the first sudden change; both a moving speed of the other of the first probe and the second probe and a moving speed of the other of the third probe and the fourth probe range from 10 nm/s to 1 μm/s; and both the thickness of the first oxide layer and the thickness of the second oxide layer range from 0.1 nm to 5 nm.

An example 23 provided in the present application, including the example 21, where the step of based on resistance monitoring, inserting the other of the first probe and the second probe into the first oxide layer and enabling the other to be in contact with the first electrode includes:
moving the other that is of the first probe and the second probe and that serves as a first auxiliary probe toward the first oxide layer, and monitoring a resistance value between the first probe and the second probe in real time;
monitoring a first sudden change of the resistance value, and continuing to move the first auxiliary probe; and
monitoring a second sudden change of the resistance value, and stopping movement of the first auxiliary probe when the second sudden change occurs, where the first auxiliary probe is in contact with and electrically connected to the surface of the first electrode of the Josephson junction at this time; and
the step of the based on resistance monitoring, inserting the other of the third probe and the fourth probe into the second oxide layer and enabling the other to be in contact with the second electrode includes:
moving the other that is of the third probe and the fourth probe and that serves as a second auxiliary probe toward the second oxide layer, and monitoring a resistance value between the third probe and the fourth probe in real time;
monitoring a first sudden change of the resistance value, and continuing to move the second auxiliary probe; and
monitoring a second sudden change of the resistance value, and stopping movement of the second auxiliary probe when the second sudden change occurs, where the second auxiliary probe is in contact with and electrically connected to the surface of the second electrode of the Josephson junction at this time.

An example 24 provided in the present application, including the example 23, where a distance between a contact position of the one of the first probe and the second probe and the Josephson junction is greater than a distance between an insertion position of the first auxiliary probe and the Josephson junction; and a distance between a contact position of the one of the third probe and the fourth probe and the Josephson junction is greater than a distance between an insertion position of the second auxiliary probe and the Josephson junction.

An example 25 provided in the present application, including the example 24, where the first sudden change is that a resistance value decreases from 1 MΩ or more to 1-10 KΩ; the second sudden change is that a resistance value changes to 100-1000 Ω; and both the thickness of the first oxide layer and the thickness of the second oxide layer range from 0.1 nm to 5 nm.

An example 26 provided in the present application: a measurement system of a junction resistance of a superconducting qubit, where the superconducting qubit includes a Josephson junction, the Josephson junction includes a first electrode and a second electrode, and the measurement system includes:
a first probe unit, configured to break down a first oxide layer formed on a surface of the first electrode;
a second probe unit, configured to break down a second oxide layer formed on a surface of the second electrode; and
a test instrument unit, where the test instrument unit is connected to the first probe unit and the second probe unit, to apply a voltage for implementing electrical breakdown, apply a test current through a broken-down first oxide layer, the Josephson junction, and a broken-down second oxide layer, and measure a voltage between the broken-down first oxide layer and the broken-down second oxide layer.

In the foregoing examples provided in the present application, a probe apparatus controls a probe to be inserted into but not penetrate through an oxide layer on a surface of an electrode of a Josephson junction, and applies an electrical breakdown signal between two probes on a same side of the Josephson junction, to break down the oxide layer below the two probes, so that a broken-down oxide layer loses insulation performance. In this way, the probes form a conductive connection with the electrode of Josephson junction. Compared with a manner in the prior art in which a probe is directly inserted into an electrode of a Josephson junction, the present application can prevent the probe from being in direct and rough contact with the electrode. This does not cause a performance loss of a superconducting qubit, for example, both a coherence time and a bit frequency of the superconducting qubit are not affected, and is very applicable to a superconducting quantum chip.

In the foregoing examples provided in the present application, a probe apparatus controls a probe to exactly penetrate through an oxide layer on a surface of an electrode of a Josephson junction, so that the probe forms a conductive connection with the electrode of the Josephson junction. Compared with a manner in the prior art in which a probe is directly inserted into an electrode of a Josephson junction, the present application can prevent the probe from being in direct and rough contact with the electrode. This does not cause a performance loss of a superconducting qubit, for example, both a coherence time and a bit frequency of the superconducting qubit are not affected, and is very applicable to a superconducting quantum chip.

In the foregoing examples provided in the present application, a measurement method and measurement system of a junction resistance of a superconducting qubit use a probe apparatus in some examples, so that electrodes on two sides of a Josephson junction form conductive connections with probes. A junction resistance measurement module is separately connected to the probes on the two sides of the Josephson junction to implement resistance measurement. Because the probes are not in direct contact with the electrodes, performance of the superconducting qubit is not lost when a resistance of the Josephson junction is accurately measured.

In the foregoing examples provided in the present application, according to a measurement method of a junction resistance of a superconducting qubit, oxide layers formed on surfaces of electrodes on two sides of a Josephson junction are electrically broken down, a test current through a broken-down oxide layer, the Josephson junction, and a broken-down oxide layer is applied, a voltage between the broken-down oxide layers on the two sides is measured, and the junction resistance of the superconducting qubit is determined based on the voltage and the test current. In this way, impact of the oxide layers on resistance value measurement can be avoided, so that a resistance of the Josephson junction can be obtained more accurately.

In the foregoing examples provided in the present application, according to the measurement method of the junction resistance of the superconducting qubit, the first oxide layer formed on the surface of the first electrode is electrically broken down, the second oxide layer formed on the surface of the second electrode is electrically broken down, the test current through the broken-down first oxide layer, the Josephson junction, and the broken-down second oxide layer is applied, the voltage between the broken-down first oxide layer and the broken-down second oxide layer is measured, and the junction resistance of the qubit is determined based on the voltage and the test current. In this way, impact of the oxide layers on resistance value measurement can be avoided, so that a resistance of the Josephson junction can be obtained more accurately.

In the foregoing examples provided in the present application, a change situation of a pressure signal exerted on a probe is monitored in real time, so that the probe can be precisely inserted downward a boundary of a first film layer and a second film layer, and the probe forms a good electrical connection with the second film layer without damaging the second film layer.

In the foregoing examples provided in the present application, a probe can be precisely inserted downward a boundary of an oxide layer of an electrode of a Josephson junction and the electrode, and the probe can form a good electrical connection with the electrode of the Josephson junction without damaging the electrode, so that performance of the Josephson junction is not affected.

In the foregoing examples provided in the present application, only two probes are required, so that a structure is simple. In addition, a change situation of pressure signals exerted on the probes is monitored in real time, so that each of the probes can be precisely inserted downward a boundary of oxide layers of two electrodes of a Josephson junction and the electrodes, and the probes can form good electrical connections with the electrodes of the Josephson junction without damaging the electrodes. On this basis, a resistance of the Josephson junction is measured, an operation process is simple, and measurement accuracy may be effectively improved.

In the foregoing examples provided in the present application, a measurement system and method of a junction resistance of a superconducting qubit use a probe apparatus in some examples, so that electrodes on two sides of a Josephson junction form conductive connections with probes. A junction resistance measurement module is separately connected to the probes on the two sides of the Josephson junction to implement resistance measurement. Because the probes exactly penetrate through oxide layers on surfaces of the electrodes of the Josephson junction, performance of the superconducting qubit is not lost when a resistance of the Josephson junction is accurately measured.

In the foregoing examples provided in the present application, according to a measurement method of a junction resistance of a superconducting qubit, based on pressure monitoring, a probe exactly reaches a boundary of an oxide layer and an electrode, oxide layers on two sides of a Josephson junction are electrically broken down, a test current through a broken-down oxide layer, the Josephson junction, and a broken-down oxide layer is applied, a voltage is measured, and the junction resistance of the qubit may be determined based on the voltage and the test current. In this way, measurement accuracy can be effectively improved, impact on the oxide layers can be reduced, and damage to the electrodes by the probe can be reduced as much as possible.

In the foregoing examples provided in the present application, a change situation of a resistance value between a first probe and a second probe is monitored in real time, so that the second probe can be precisely inserted downward a boundary of a first film layer and a second film layer, and the second probe forms a good electrical connection with the second film layer without damaging the second film layer.

In the foregoing examples provided in the present application, in a process of measuring a junction resistance of a superconducting qubit, a change situation of a resistance between probes is monitored in real time, so that the probe can be precisely inserted downward a boundary of an oxide layer of an electrode of a Josephson junction and the electrode, and the probe can form a good electrical connection with the electrode of the Josephson junction without damaging the electrode. On this basis, a resistance of the Josephson junction is measured, and measurement accuracy may be effectively improved.

In the foregoing examples provided in the present application, in a process of measuring a junction resistance of a superconducting qubit, a quantity of probes to be used may be reduced.

### BRIEF DESCRIPTION OF THE DRAWINGS

FIG. 1 is a schematic structural diagram of a qubit of a superconducting quantum chip.

FIG. 2 is a schematic structural diagram of another qubit of a superconducting quantum chip.

FIG. 3 is a schematic structural diagram of a Josephson junction.

FIG. 4 is a schematic structural diagram 1 of a probe apparatus according to an embodiment of the present application.

FIG. 5 is a schematic diagram 1 of an insertion position according to an embodiment of the present application.

FIG. 6 is a schematic structural diagram 2 of a probe apparatus according to an embodiment of the present application.

FIG. 7 is a schematic structural diagram 3 of a probe apparatus according to an embodiment of the present application.

FIG. 8 is a schematic structural diagram 1 of a measurement system of a junction resistance of a superconducting qubit according to an embodiment of the present application.

FIG. 9 is a schematic flowchart 1 of a measurement method of a junction resistance of a superconducting qubit according to an embodiment of the present application.

FIG. 10 is a schematic flowchart 2 of a measurement method of a junction resistance of a superconducting qubit according to an embodiment of the present application.

FIG. 11 is a schematic diagram of an implementation of a measurement method of a junction resistance of a superconducting qubit according to an embodiment of the present application.

FIG. 12 is a schematic structural diagram 2 of a measurement system of a junction resistance of a superconducting qubit according to an embodiment of the present application.

FIG. 13 is a schematic flowchart 1 of an electrical contact connection method according to an embodiment of the present application.

FIG. 14 is a schematic structural diagram 1 of an electrical contact connection system according to an embodiment of the present application.

FIG. 15 is a schematic structural diagram 4 of a probe apparatus according to an embodiment of the present application.

FIG. 16 is a schematic diagram in which two probes are inserted into two sides of a Josephson junction according to an embodiment of the present application.

FIG. 17 is a schematic structural diagram 3 of a measurement system of a junction resistance of a superconducting qubit according to an embodiment of the present application.

FIG. 18 is a schematic diagram of a measurement circuit of a junction resistance of a superconducting qubit according to an embodiment of the present application.

FIG. 19 is a schematic flowchart 3 of a measurement method of a junction resistance of a superconducting qubit according to an embodiment of the present application.

FIG. 20 is a schematic flowchart 4 of a measurement method of a junction resistance of a superconducting qubit according to an embodiment of the present application.

FIG. 21 is a schematic structural diagram 4 of a measurement system of a junction resistance of a superconducting qubit according to an embodiment of the present application.

FIG. 22 is a schematic flowchart 2 of an electrical contact connection method according to an embodiment of the present application.

FIG. 23 is a schematic diagram 2 of an insertion position according to an embodiment of the present application.

FIG. 24 is a schematic structural diagram 2 of an electrical contact connection system according to an embodiment of the present application.

FIG. 25 is a schematic structural diagram 5 of a probe apparatus according to an embodiment of the present application.

FIG. 26 is a schematic structural diagram 5 of a measurement system of a junction resistance of a superconducting qubit according to an embodiment of the present application.

FIG. 27 is a schematic flowchart 5 of a measurement method of a junction resistance of a superconducting qubit according to an embodiment of the present application.

FIG. 28 is a schematic diagram 3 of an insertion position according to an embodiment of the present application.

FIG. 29 is a schematic diagram 4 of an insertion position according to an embodiment of the present application.

### DETAILED DESCRIPTION OF THE EMBODIMENTS

The following describes specific implementations of the present application with reference to the accompanying drawings. The advantages and features of the present application are more apparent based on the following descriptions and claims. It should be noted that, the accompanying drawings use a very simplified form and a non-accurate proportion for conveniently and clearly assisting in description of the embodiments of the present application.

In the descriptions of the present application, it should be understood that, orientations or position relationships indicated by the terms “center”, “on”, “below”, “left”, “right”, and the like are orientations or position relationships based on the accompanying drawings. These terms are merely intended to facilitate the description of the present application and simplify the description, rather than indicating or implying that the referred apparatus or element must have a particular orientation or be constructed and operated in a particular orientation. Therefore, these terms should not be interpreted as limiting the present application.

In addition, the terms “first” and “second” are merely intended for a purpose of description, and shall not be understood as an indication or implication of relative importance or implicit indication of the number of indicated technical features. Therefore, the features defined by “first” and “second” may indicate or imply that one or more of the features are included. In the descriptions of the present application, “a plurality of” means at least two, for example, two or three, unless otherwise specifically stated.

According to different physical systems used for constructing a qubit, the qubit includes a superconducting quantum circuit, a semiconductor quantum dot, an ion trap, a diamond vacancy, a topology quantum, a photon, and the like in a physical implementation.

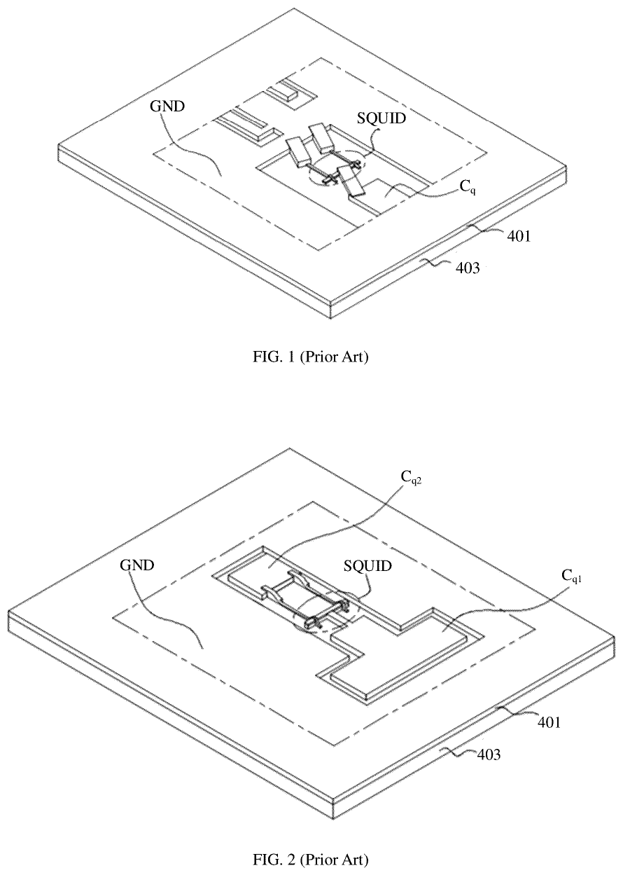

Superconducting quantum computing is currently the fastest and best progressing method to implement solid-state quantum computing. For a superconducting quantum chip, a structure of a qubit may use a single grounded capacitor, and a superconducting quantum interference device which one end is grounded and the other end is connected to the capacitor. In addition, the capacitor is usually a cross-shaped parallel plate capacitor. Refer to FIG. 1. A capacitor plate C_{q} is surrounded by a ground plane (GND), and there is a gap between the capacitor plate C_{q} and the ground plane (GND). One end of a superconducting quantum interference device (SQUID) is connected to the capacitor plate C_{q}, and the other end is connected to the ground plane (GND). Besides, a structure of a qubit may alternatively use two grounded capacitors and a superconducting quantum interference device connected to each of the two grounded capacitors. Refer to FIG. 2. A first capacitor electrode plate C_{q1}, a second capacitor electrode plate C_{q2}, and a superconducting quantum interference device (SQUID) are surrounded by a ground plane (GND), and there are gaps between the first capacitor electrode plate C_{q1} and the ground plane (GND), and between the second capacitor electrode plate C_{q2} and the ground plane (GND). One end of the superconducting quantum interference device (SQUID) is connected to the first capacitor electrode plate C_{q1}, and the other end is connected to the second capacitor electrode plate C_{q2}.

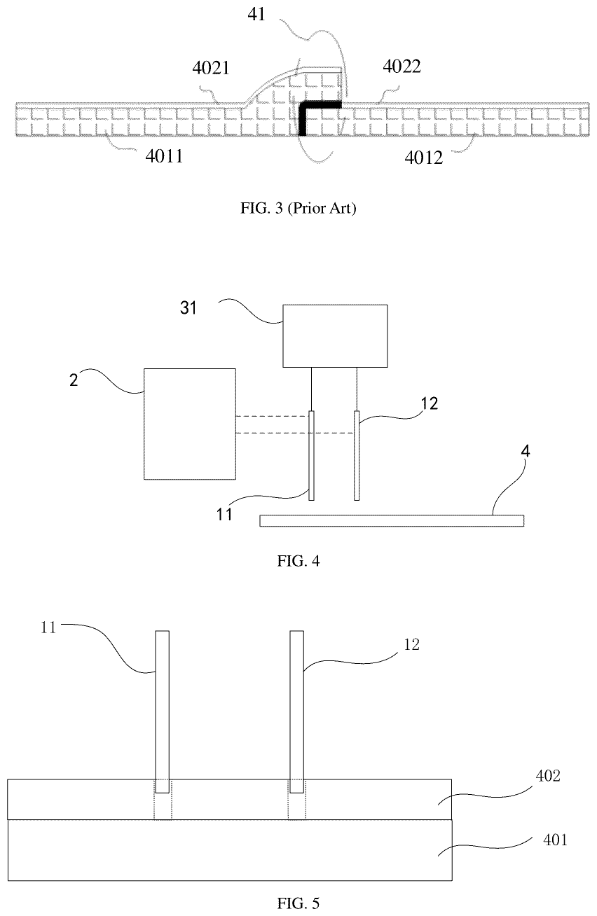

A key structure of the superconducting quantum chip is a superconducting qubit, a key structure of the superconducting qubit is a Josephson junction, and performance quality of the Josephson junction directly affects performance of the qubit. The Josephson junction is a special device formed by sandwiching a thin layer of an insulator between two electrodes. As shown in FIG. 3, a Josephson junction 41 includes a first electrode 4011, a second electrode 4012, and an insulator between the first electrode 4011 and the second electrode 4012. The first electrode 4011 may be extended from the Josephson junction 41 to one side, and the second electrode 4012 may be extended from the Josephson junction 41 to an opposite side. To ensure performance of the superconducting quantum chip, frequency parameters of the superconducting qubit must be strictly controlled. A representation of a normal-temperature resistance of the superconducting qubit is important information about the frequency parameters, and a resistance of the Josephson junction is the key to the representation of the normal-temperature resistance of the superconducting qubit. Therefore, the resistance of the Josephson junction needs to be accurately measured to determine whether the superconducting quantum chip is qualified. However, there is currently no resistance measurement solution specifically for the superconducting quantum chip. In the measurement that is of the junction resistance of the Josephson junction and that is performed in the present application, a main insertion downward position is a part that is of the electrodes and that is extended from the Josephson junction.

### Embodiment 1

Refer to FIG. 4. A first embodiment of the present application provides a probe apparatus, configured to measure a superconducting quantum chip. The probe apparatus includes a probe set, a probe control mechanism 2, and a power supply module 31. The probe set includes two probes that are independent, for example, a first probe 11 and a second probe 12. It should be noted that dashed lines in FIG. 4 represent control connections, and solid lines in the figure represent signal connections.

The probe control mechanism is configured to control the probe set to be connected to an oxide layer on a surface of an electrode of a Josephson junction on the superconducting quantum chip. For example, the probe control mechanism 2 is configured to control the first probe 11 and the second probe 12 to be inserted downward one side of the Josephson junction on the superconducting quantum chip 4, and make the first probe 11 and the second probe 12 inserting into but not penetrating though the oxide layer on the surface of the electrode on the one side of the Josephson junction, that is, the probe is inserted into the oxide layer, and a depth of which the probe is inserted into the oxide layer is less than or equal to a thickness of the oxide layer. Alternatively, the probe is in contact with a surface that is of the oxide layer and that is away from the electrode. That is, a depth of which the probe is inserted into the oxide layer is 0. In other words, the probe is not inserted into the oxide layer.

The electrode of the Josephson junction on the superconducting quantum chip is usually made of a material such as aluminum. The aluminum has a strong activity, and quickly forms a non-conductive oxide layer on a surface after being in contact with air. Although presence of the oxide layer protects the Josephson junction, it is extremely inconvenient to test a resistance of the Josephson junction for studying performance of a finished Josephson junction.

In this embodiment, insertion downward forces of the first probe 11 and the second probe 12 are related to insertion depths of the first probe 11 and the second probe 12. Larger insertion downward forces indicate larger insertion depths of the first probe 11 and the second probe 12. The insertion downward forces should be set as follows: The first probe 11 and the second probe 12 are not in contact with the electrode, or are exactly in contact with the electrode. The “not in contact with the electrode” indicates that the depth of which the probe is inserted into the oxide layer is less than the thickness of the oxide layer, and the “exactly in contact with the electrode” indicates that the depth of which the probe is inserted into the oxide layer is equal to the thickness of the oxide layer. As shown in FIG. 5, the first probe 11 and the second probe 12 are inserted into an oxide layer 402 on a surface of an electrode 401 of the Josephson junction, but do not penetrate through the oxide layer 402. It should be noted that, in another embodiment other than this embodiment, the insertion downward forces may be controlled according to a requirement, to control the insertion depths of the first probe 11 and the second probe 12, for example, exactly penetrating though the oxide layer but stopping on the contacting surface of the electrode and the oxide layer or the like. The “exactly penetrating the oxide layer” indicates that the depth of which the probe is inserted into the oxide layer is equal to the thickness of the oxide layer.

In this embodiment, the power supply module 31 is configured to apply an electrical breakdown signal between the first probe 11 and the second probe 12, to break down the oxide layer below two insertion positions on the one side of the Josephson junction, so that the first probe 11 and the second probe 12 form a conductive connection with the electrode on the one side of the Josephson junction. The power supply module 31 is connected to both the first probe 11 and the second probe 12, and uses the first probe 11 and the second probe 12 as two output ends, so that the electrical breakdown signal is output to act on the oxide layer between the first probe 11 and the second probe 12, to break down the oxide layer below the two insertion positions on the one side of the Josephson junction. After the oxide layer is broken down, insulation performance is lost, so that the first probe 11 and the second probe 12 form the conductive connection with the electrode on the one side of the Josephson junction. As shown in FIG. 5, the oxide layer 402 between the first probe 11 and the second probe 12, namely, the oxide layer in dashed boxes in the figure, is broken down.

The probe apparatus in this embodiment controls the first probe 11 and the second probe 12 to be inserted into but not penetrate through the oxide layer on the surface of the electrode of the Josephson junction, and applies the electrical breakdown signal between the first probe 11 and the second probe 12 on the same side of the Josephson junction, to break down the oxide layer between the first probe 11 and the second probe 12, so that the broken-down oxide layer loses insulation performance, and the first probe 11 and the second probe 12 form the conductive connection with the electrode of the Josephson junction. Compared with a manner in the prior art in which a probe is directly inserted into an electrode of a Josephson junction, the present application can prevent the probe from being in direct contact with the electrode of the Josephson junction. This does not cause a performance loss of a superconducting qubit, for example, both a coherence time and a bit frequency of the superconducting qubit are not affected. Therefore, the probe apparatus in this embodiment is very applicable to the superconducting quantum chip.

It should be noted that, because a structure of the Josephson junction is that a layer of an insulator is sandwiched between two electrodes, there is an electrode on each of two sides of the Josephson junction, and the first probe 11 and the second probe 12 form the conductive connection with the electrode on only one side of the Josephson junction. Therefore, the electrode on the other side of the Josephson junction may form a conductive connection in a same manner.

In this embodiment, after the oxide layer on the surface of the electrode is broken down by using the electrical breakdown signal, a medium with an insulation property, such as an oxide near a tip, becomes a conductive medium, and the first probe 11 and the second probe 12 form good electrical contact with the surface of the electrode, to facilitate measurement of the superconducting quantum chip. For example, a resistance or another electrical performance of the superconducting quantum chip may be measured. Details are not described in this embodiment.

### Embodiment 2

A second embodiment of the present application provides another probe apparatus. The probe apparatus includes all technical features of the first embodiment. To be specific, based on Embodiment 1, this embodiment adds a specific structure of the probe control mechanism, and describes a quantity of probe sets or the like. An overall structure of the probe apparatus is described in Embodiment 1. To save space, details are not described herein. For details, refer to Embodiment 1.

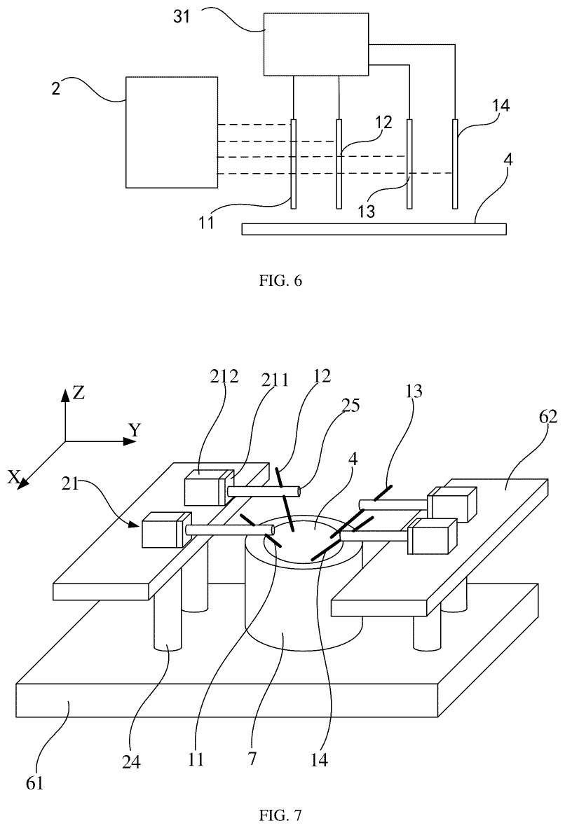

Refer to FIG. 6. In this embodiment, two probe sets are used as an example, and include the first probe 11, the second probe 12, a third probe 13, and a fourth probe 14. The first probe 11 and the second probe 12 are a set, and the third probe 13 and the fourth probe 14 are a set. That is, the probe sets include a first probe set and a second probe set.

The probe control mechanism 2 is further configured to control the third probe 13 and the fourth probe 14 to be inserted downward the other side of the Josephson junction, so that the third probe 13 and the fourth probe 14 are inserted into but do not penetrate through an oxide layer on a surface of an electrode on the other side of the Josephson junction. That is, the probe control mechanism is configured to control: two probes of the first probe set to be separately inserted downward one side of the Josephson junction, and two probes of the second probe set to be separately inserted downward the other side of the Josephson junction, so that the two probe sets are respectively connected to oxide layers on surfaces of electrodes on the two sides of the Josephson junction.

The power supply module 31 is further configured to apply an electrical breakdown signal between the third probe 13 and the fourth probe 14, to break down the oxide layer below two insertion positions on the other side of the Josephson junction, so that the third probe 13 and the fourth probe 14 form a conductive connection with the electrode on the other side of the Josephson junction. That is, the power supply module is configured to apply the electrical breakdown signal between the probes in the first probe set and between the probes in the second probe set, to break down the oxide layers on the two sides of the Josephson junction.

Because a structure of the Josephson junction is that a layer of an insulator is sandwiched between two electrodes, there is an electrode on each of the two sides of the Josephson junction, and the first probe 11 and the second probe 12 form a conductive connection with the electrode on only one side of the Josephson junction. Therefore, the third probe 13 and the fourth probe 14 of the probe apparatus in this embodiment form the conductive connection with the electrode on the other side of the Josephson junction in a same manner as the first embodiment.

In this embodiment, insertion downward forces of the first probe 11, the second probe 12, the third probe 13, and the fourth probe 14 are the same. A specific insertion downward force, a tip diameter, and the like are all described in Embodiment 1, and details are not described herein again. In addition, the insertion downward force of each probe may be different, and an appropriate insertion downward force may be selected based on an actual insertion downward position, a probe material, and the like.

To obtain, in real time, the insertion downward force in a process in which the first probe 11, the second probe 12, the third probe 13, and the fourth probe 14 are inserted downward, in this embodiment, the probe control mechanism 2 includes a micro force sensor (not shown in the figure). The micro force sensor is connected to the probes in the probe sets, and the micro force sensor is configured to detect an insertion downward force of the probe sets. To be specific, the micro force sensor is configured to detect the insertion downward forces of the first probe 11, the second probe 12, the third probe 13, and the fourth probe 14. The probe control mechanism 2 may accurately control the insertion downward forces of the first probe 11, the second probe 12, the third probe 13, and the fourth probe 14 based on the insertion downward forces detected by the micro force sensor. Possibly, there are four micro force sensors, which are respectively connected to the first probe 11, the second probe 12, the third probe 13, and the fourth probe 14.

The setting of the electrical breakdown signal should ensure that the oxide layer can be broken down without affecting the electrode. For example, in an application scenario, a voltage of the electrical breakdown signal ranges from 0.5 V to 5 V, for example, 1 V, 2 V, 3 V, or 4 V; and a current of the electrical breakdown signal is less than or equal to 10 μA, for example, 1 μA, 3 μA, 5 μA, 7 μA, or 9 μA.

In addition, a quantity of displacement adjustment components needs to be the same as a quantity of the probes. Therefore, in this embodiment, the probe control mechanism includes four displacement adjustment components. Two displacement adjustment components are respectively connected to the first probe and the second probe, and respectively configured to control the first probe and the second probe to be displaced in a multi-degree-of-freedom direction and to be inserted downward the one side of the Josephson junction. The other two displacement adjustment components are further respectively connected to the third probe and the fourth probe, and respectively configured to control the third probe and the fourth probe to be displaced in a multi-degree-of-freedom direction and to be inserted downward the other side of the Josephson junction.

In some specific application scenarios, each displacement adjustment component includes a first displacement stage with first displacement precision and a second displacement stage with second displacement precision, and the first displacement precision is higher than the second displacement precision.

In some specific application scenarios, the displacement adjustment component further includes a connecting arm. The connecting arm is connected to the first displacement stage and the micro force sensor, so that the first displacement stage drives the probe to move.

In another embodiment other than this embodiment, a person skilled in the art may correspondingly set quantities of probe control mechanisms, micro force sensors, and the like based on a specific quantity of probe sets, for example, set quantities of displacement adjustment components, probe arms, and the like.

### Embodiment 3

Refer to FIG. 7. According to a same invention concept as the probe apparatus in the second embodiment, a third embodiment of the present application provides a probe apparatus. It should be noted that the power supply module 31 is omitted in FIG. 7.

The probe control mechanism includes four displacement adjustment components 21. The four displacement adjustment components 21 are respectively connected to the first probe 11, the second probe 12, the third probe 13, and the fourth probe 14, and respectively configured to control the first probe 11, the second probe 12, the third probe 13, and the fourth probe 14 to be displaced in a multi-degree-of-freedom direction, and to be respectively inserted downward two opposite sides of the Josephson junction. By using the four displacement adjustment components 21, each of the first probe 11, the second probe 12, the third probe 13, and the fourth probe 14 can be independently controlled, without affecting each other. Positions of the first probe 11, the second probe 12, the third probe 13, and the fourth probe 14 relative to the superconducting quantum chip 4 are not fixed. Therefore, the first probe 11, the second probe 12, the third probe 13, and the fourth probe 14 need to be first controlled to be moved to a position of the Josephson junction, and then the first probe 11, the second probe 12, the third probe 13, and the fourth probe 14 are controlled to be inserted downward the electrodes of the Josephson junction.

To make full use of space, in this embodiment, two displacement adjustment components 21 configured to connect the first probe 11 and the second probe 12 are disposed on the one side of the superconducting quantum chip 4, and two displacement adjustment components 21 configured to connect the third probe 13 and the fourth probe 14 are disposed on the other side of the superconducting quantum chip 4. In other words, the four displacement adjustment components 21 are distributed in pairs on the two sides of the superconducting quantum chip 4.

Specifically, the displacement adjustment component 21 includes a first displacement stage 211 and a second displacement stage 212. The displacement adjustment component 21 could be set on a support plate 62. The support plate 62 could be set on a support column 24. The probe apparatus includes a base 61 and the base 61 is used to support other parts.

The first displacement stage 211 is connected to the second displacement stage 212. Because the second displacement stage 212 has second displacement precision, the first displacement stage 211 may be displaced with the second displacement precision in a spatial three-dimensional degree-of-freedom direction.

First displacement stages 211 of the four displacement adjustment components 21 are respectively connected to the first probe 11, the second probe 12, the third probe 13, and the fourth probe 14. Because the first displacement stages 211 have first displacement precision, the first probe 11, the second probe 12, the third probe 13, and the fourth probe 14 may be displaced with the first displacement precision higher than the second displacement precision.

The second displacement precision is relatively low, and coarse displacement adjustment may be implemented, so that the first probe 11, the second probe 12, the third probe 13, and the fourth probe 14 are displaced more quickly to the position of the Josephson junction. The first displacement precision is relatively high, and fine displacement adjustment may be implemented, so that the first probe 11 and the second probe 12 are accurately displaced to the one side of the Josephson junction, and the third probe 13 and the fourth probe 14 are accurately displaced to the other side of the Josephson junction.

Possibly, the displacement adjustment component 21 further include a probe arm 25, and the first displacement stages 211 of the four displacement adjustment components 21 are respectively connected to the first probe 11, the second probe 12, the third probe 13, and the fourth probe 14 via probe arms 25. The probe arm 25 may keep the first displacement stage 211 and the second displacement stage 212 as far away from the superconducting quantum chip 4 as possible, to leave sufficient operating space for the superconducting quantum chip 4.

### Embodiment 4

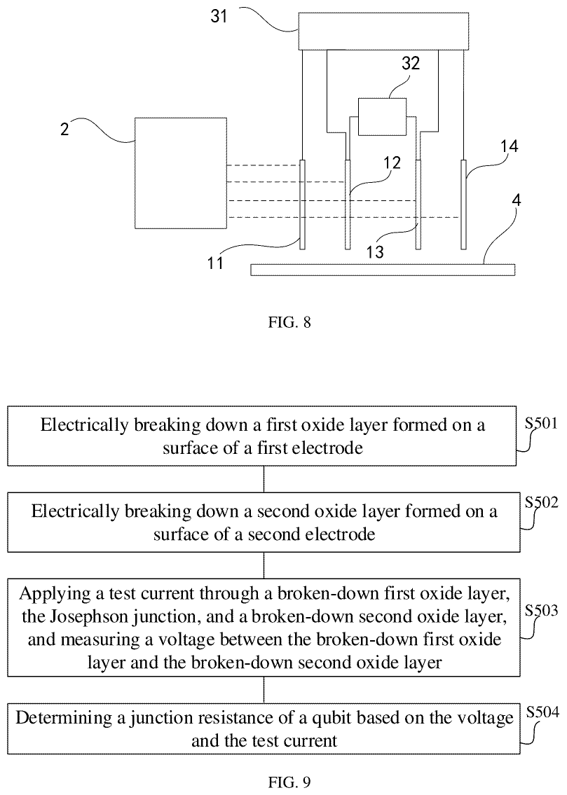

Refer to FIG. 8. A fourth embodiment of the present application provides a measurement system of a junction resistance of a superconducting qubit, including a junction resistance measurement module 32 and the probe apparatus in the second embodiment or the third embodiment.

The junction resistance measurement module 32 is configured to measure a resistance between one of the first probe 11 and the second probe 12 and one of the third probe 13 and the fourth probe 14. The junction resistance measurement module 32 forms a conduction path with a Josephson junction via one of the first probe 11 and the second probe 12 and one of the third probe 13 and the fourth probe 14, so that a resistance of the Josephson junction can be measured. For example, a positive electrode of the junction resistance measurement module 32 is connected to the second probe 12, and a negative electrode of the junction resistance measurement module 32 is connected to the third probe 13, to measure the resistance of the Josephson junction.

The measurement system of the junction resistance of the superconducting qubit in this embodiment uses the probe apparatus in the second embodiment or the third embodiment, so that the electrodes on the two sides of the Josephson junction form conductive connections with the probes. The junction resistance measurement module is separately connected to the probes on the two sides of the Josephson junction to implement resistance measurement. Because the probes are not in direct contact with the electrodes of the Josephson junction, physical damage is not caused to the electrodes of the Josephson junction, so that performance of the superconducting qubit is not lost when the resistance of the Josephson junction is accurately measured. In addition, because the probes are inserted into oxide layers on surfaces of the electrodes of the Josephson junction, stability is ensured, so that reliability and accuracy of a measurement result of the resistance of the Josephson junction is ensured.

### Embodiment 5

This embodiment provides a measurement method of a junction resistance of a superconducting qubit. The superconducting qubit includes a Josephson junction, and the Josephson junction includes a first electrode and a second electrode. As shown in FIG. 9, the method includes the following steps.

S501: electrically breaking down a first oxide layer formed on a surface of the first electrode.

S502: electrically breaking down a second oxide layer formed on a surface of the second electrode.

S503: applying a test current through an electrically broken-down first oxide layer, the Josephson junction, and an electrically broken-down second oxide layer, and measuring a voltage between the broken-down first oxide layer and the broken-down second oxide layer.

S504: determining the junction resistance of the superconducting qubit based on the voltage and the test current.

In this embodiment, the first oxide layer formed on the surface of the first electrode is electrically broken down, the second oxide layer formed on the surface of the second electrode is electrically broken down, the test current through the broken-down first oxide layer, the Josephson junction, and the broken-down second oxide layer is applied, the voltage between the first oxide layer and the second oxide layer is measured, and the junction resistance of the superconducting qubit is determined based on the voltage and the test current. Compared with the prior art, in this embodiment, the first oxide layer formed on the surface of the first electrode and the second oxide layer formed on the surface of the second electrode are electrically broken down, and then the junction resistance is measured. In this way, impact of the oxide layers on resistance value measurement can be avoided, so that a resistance of the Josephson junction may be obtained more accurately.

The following further describes, with reference to the accompanying drawings, implementation details of the measurement method of the junction resistance of the superconducting qubit according to this embodiment.

In some implementations of this embodiment, the step of electrically breaking down a first oxide layer formed on a surface of the first electrode includes: first enabling a first probe and a second probe to be in contact with the first oxide layer; and then forming a potential difference between the first probe and the second probe, for example, applying a breakdown voltage, to electrically break down the first oxide layer. A manner in which the first probe and the second probe are in contact with the first oxide layer is exemplarily as follows. One of the first probe and the second probe is inserted into the first oxide layer, and an insertion depth is less than or equal to a thickness of the first oxide layer. It should be noted that a hardness of the inserted probe is greater than a hardness of the first oxide layer. The other of the first probe and the second probe is in contact with the surface of the first oxide layer, and a hardness of the probe in contact is less than the hardness of the first oxide layer.

In some other implementations, at the same time when the potential difference is formed between the first probe and the second probe to electrically break down the first oxide layer, the method further includes: applying a first protection voltage to the second electrode to reduce a potential difference between two superconducting layers of the Josephson junction. For example, another probe may be configured to be in contact with the second electrode to provide the first protection voltage for the second electrode. To implement better protection, a potential difference between the first protection voltage and the breakdown voltage applied to the first oxide layer is less than a broken-down voltage of a barrier layer of the Josephson junction, namely, a barrier voltage of the barrier layer of the Josephson junction. According to the applicant's manufacturing process and design parameters, when the barrier layer of the Josephson junction is 1-2 nm, the breakdown voltage of a barrier layer of the Josephson junction is usually less than 3-5 V. Therefore, the potential difference between the first protection voltage and the breakdown voltage applied to the first oxide layer is less than the breakdown voltage of a barrier layer of the Josephson junction, for example, less than 3 V, to play a protection role.

For example, when the first probe is connected to +3 V and the second probe is grounded (GND), the second electrode may be connected to a protection voltage of +1.5 V. In this way, a potential difference between the first electrode and the second electrode is prevented from being too large, so that it is ensured that the Josephson junction is not broken down when electrical breakdown is implemented on the first oxide layer.

In some implementation of this embodiment, the step of electrically breaking down a second oxide layer formed on a surface of the second electrode includes: first enabling a third probe and a fourth probe to be in contact with the second oxide layer; and then forming a potential difference between the third probe and the fourth probe, for example, applying a breakdown voltage, to electrically break down the second oxide layer.

In some other implementations, at the same time when the potential difference is formed between the third probe and the fourth probe to electrically break down the second oxide layer, the method further includes: applying a second protection voltage to the first electrode to reduce a potential difference between two superconducting layers of the Josephson junction.

For example, after the first oxide layer is electrically broken down by using the first probe and the second probe, positions of the two probes remain unchanged. Therefore, a protection voltage may be directly applied by using the first probe or the second probe, to prevent the Josephson junction from being electrically broken down due to an excessively large potential difference between the first electrode and the second electrode. For example, when the third probe is connected to +3 V and the fourth probe is grounded (GND), the first electrode may be connected to a protection voltage of +1.5 V. It should be noted that, when the breakdown voltage is applied to the second oxide layer to perform electrical breakdown, the first probe and the second probe are still in contact with the first electrode and the first oxide layer. In this case, when the second oxide layer is electrically broken down by using the third probe and the fourth probe, a part of the breakdown voltage may flow to the first probe and/or the second probe through the Josephson junction. Therefore, in this step, applying the protection voltage to the first electrode becomes a feasible option. Similarly, for example, a potential difference between the breakdown voltage and the protection voltage is less than 3 V, to ensure safety of the Josephson junction.

It should be noted that the first oxide layer, the first electrode, the Josephson junction, the second electrode, and the second oxide layer form a series circuit model. If the test current is applied and the corresponding voltage is measured by directly enabling the probes to be in contact with the surface of the first electrode and the surface of the second electrode without performing electrical breakdown, the obtained junction resistance is easily affected by resistances of the first oxide layer and the second oxide layer. In this embodiment, the first probe and the second probe are in contact with the first oxide layer of the first electrode, the first oxide layer located in a contact area of the first probe and a contact area of the second probe is electrically broken down, the third probe and the fourth probe are in contact with the second oxide layer of the second electrode, and the second oxide layer located in a contact area of the third probe and a contact area of the fourth probe is electrically broken down. Then, one of the first probe and the second probe and one of the third probe and the fourth probe may be used for applying a constant current through the Josephson junction and measuring a corresponding voltage. In this way, the junction resistance of the superconducting qubit may be determined based on the voltage and the constant current.

### Embodiment 6

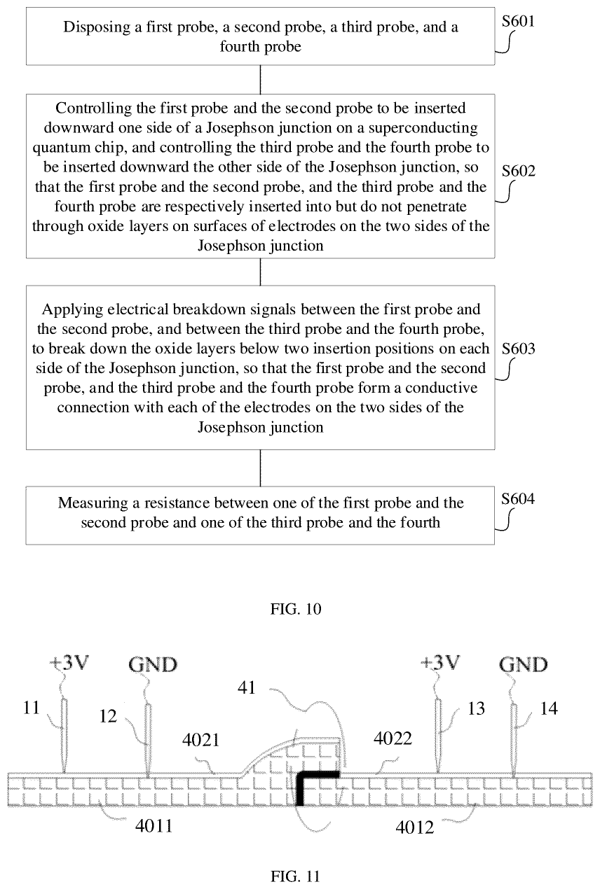

Refer to FIG. 10. A sixth embodiment of the present application provides a measurement method of a junction resistance of a superconducting qubit. The method may be obtained through further optimization based on Embodiment 5, or may exist not based on Embodiment 5. The method includes the following steps.

S601: disposing a first probe, a second probe, a third probe, and a fourth probe.

S602: controlling the first probe and the second probe to be inserted downward one side of a Josephson junction on a superconducting quantum chip, and controlling the third probe and the fourth probe to be inserted downward the other side of the Josephson junction, so that the first probe and the second probe, and the third probe and the fourth probe are respectively inserted into but do not penetrate through oxide layers on surfaces of electrodes on the two sides of the Josephson junction, where the “inserted into but not penetrate” indicates that an insertion depth is less than a thickness of the oxide layer.

S603: applying electrical breakdown signals between the first probe and the second probe, and between the third probe and the fourth probe, to break down the oxide layers below two insertion positions on each side of the Josephson junction, so that the first probe and the second probe, and the third probe and the fourth probe form a conductive connection with each of the electrodes on the two sides of the Josephson junction.

S604: measuring a resistance between one of the first probe and the second probe and one of the third probe and the fourth probe.

The electrode of the Josephson junction is usually made of a material such as aluminum. The aluminum has a strong activity, and quickly forms a non-conductive oxide layer on a surface after being in contact with air. Insertion downward forces of the first probe, the second probe, the third probe, and the fourth probe are related to insertion depths of the first probe, the second probe, the third probe, and the fourth probe. Larger insertion downward forces indicate larger insertion depths of the first probe, the second probe, the third probe, and the fourth probe. The insertion downward forces should be set as follows: The first probe, the second probe, the third probe, and the fourth probe are not in contact with the electrodes, or exactly in contact with the electrodes. In this embodiment, the insertion downward forces of the first probe, the second probe, the third probe, and the fourth probe are the same.

The electrical breakdown signals act on oxide layers between the first probe and the second probe, and between the third probe and the fourth probe, to break down the oxide layers below the two insertion positions on each side of the Josephson junction. After the oxide layers are broken down, insulation performance is lost, so that the first probe and the second probe form a conductive connection with the electrode on the one side of the Josephson junction, and the third probe and the fourth probe form a conductive connection with the electrode on the other side of the Josephson junction.

In the measurement method of the junction resistance of the superconducting qubit in this embodiment, the probes are controlled to be inserted into but not penetrate through the oxide layers on the surfaces of the electrodes on the two sides of the Josephson junction, and electrical breakdown is performed to break down the oxide layers between the two probes on each side of the Josephson junction. In this way, the electrodes on the two sides of the Josephson junction form conductive connections with the probes, and are respectively connected to the probes on the two sides of the Josephson junction to implement resistance measurement. Because the probes are not in direct contact with the electrodes of the Josephson junction, physical damage is not caused to the electrodes of the Josephson junction, so that performance of the superconducting qubit is not lost when a resistance of the Josephson junction is accurately measured. In addition, because the probes are inserted into the oxide layers on the surfaces of the electrodes of the Josephson junction, stability is ensured, so that reliability and accuracy of a measurement result of the resistance of the Josephson junction is ensured.

### Embodiment 7

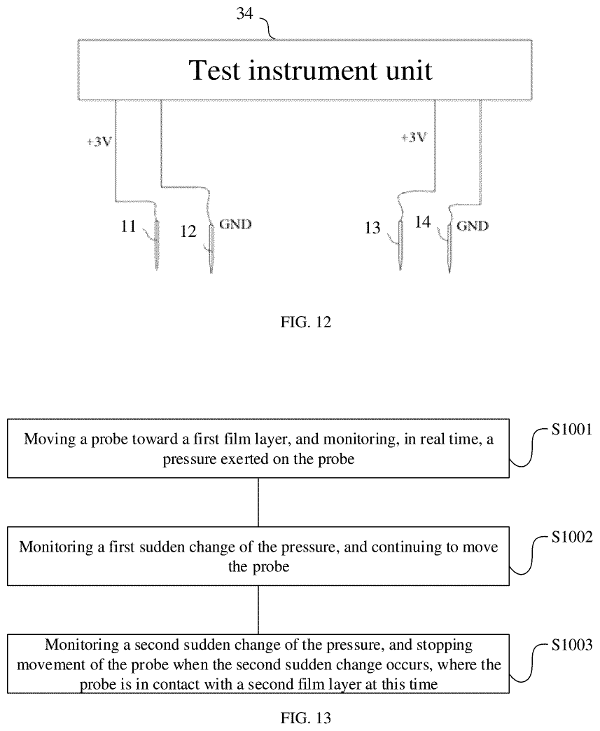

Refer to FIG. 11 and FIG. 12. A seventh embodiment of the present application provides a measurement method of a junction resistance of a superconducting qubit. The method may be obtained through further optimization based on Embodiment 5, or may exist not based on Embodiment 5. The method includes the following steps.

S701: enabling one of a first probe 11 and a second probe 12 to be in contact with a first oxide layer 4021 on a surface of a first electrode 4011, and inserting the other of the first probe 11 and the second probe 12 into the first oxide layer 4021.

S702: electrically breaking down the first oxide layer 4021 by using the first probe 11 and the second probe 12.

S703: enabling one of a third probe 13 and a fourth probe 14 to be in contact with a second oxide layer 4022 on a surface of a second electrode 4012, and inserting the other of the third probe 13 and the fourth probe 14 into the second oxide layer 4022.

S704: electrically breaking down the second oxide layer 4022 by using the third probe 13 and the fourth probe 14.

S705: measuring a resistance between one of the first probe 11 and the second probe 12 and one of the third probe 13 and the fourth probe 14.

In some implementations of this embodiment, the step of electrically breaking down the first oxide layer 4021 by using the first probe 11 and the second probe 12 may be as follows: forming a potential difference between the first probe 11 and the second probe 12, for example, applying a breakdown voltage, to electrically break down the first oxide layer 4021.

For example, an insertion depth of the one of the first probe 11 and the second probe 12 is a thickness of the first oxide layer 4021, and an insertion depth of the one of the third probe 13 and the fourth probe 14 is a thickness of the second oxide layer 4022.

For example, the first probe 11 and the second probe 12 may use a tungsten needle, and softness and hardness degrees of the first probe 11 and the second probe 12 may be adjusted by controlling a diameter of the tungsten needle.

For example, when the first electrode 4011 is made of aluminum (Al) and the first oxide layer 4021 is made of aluminum oxide, the diameter of the tungsten needle is adjusted, so that a hardness of the first probe 11 is less than a hardness of the first oxide layer 4021, and a hardness of the second probe 12 is greater than the hardness of the first oxide layer 4021 and less than a hardness of the first electrode 4011. Therefore, it may be ensured that the first probe 11 is only in contact with the surface of the first oxide layer 4021 but not inserted into the first oxide layer 4021, and the second probe 12 can penetrate through the first oxide layer 4021 but is not inserted into the first electrode 4011. In this way, a relatively low voltage may be used for breaking down the first oxide layer 4021. This may also be achieved by using different insertion downward forces. Specifically, in this case, in a circuit model from a tip of the first probe 11 to a tip of the second probe 12, an oxide layer is mainly located below the first probe 11, so that a required breakdown voltage may be reduced.

In some implementations of this embodiment, the step of electrically breaking down the second oxide layer 4022 by using the third probe 13 and the fourth probe 14 may be as follows: forming a potential difference between the third probe 13 and the fourth probe 14, for example, applying a breakdown voltage, to electrically break down the second oxide layer 4022.

In some implementations, the third probe 13 and the fourth probe 14 may use a tungsten needle, and softness and hardness degrees of the third probe 13 and the fourth probe 14 may be adjusted by controlling a diameter of the tungsten needle.

For example, when the second electrode 4012 is made of aluminum (Al) and the second oxide layer 4022 is made of aluminum oxide, the diameter of the tungsten needle is adjusted, so that a hardness of the third probe 13 is less than a hardness of the second oxide layer 4022, and a hardness of the fourth probe 14 is greater than the hardness of the second oxide layer 4022 and less than a hardness of the second electrode 4012. Therefore, it may be ensured that the third probe 13 is only in contact with the surface of the second oxide layer 4022 but not inserted into the second oxide layer 4022, and the fourth probe 14 can penetrate through the second oxide layer 4022 but is not inserted into the second electrode 4012. In this way, a relatively low voltage may be used for breaking down the second oxide layer 4022.

It should be noted that the first oxide layer 4021, the first electrode 4011, a Josephson junction 41, the second electrode 4012, and the second oxide layer 4022 form a series circuit model. If a test current is applied and a corresponding voltage is measured by directly enabling the probes to be in contact with the surface of the first electrode 4011 and the surface of the second electrode 4012 without performing electrical breakdown, the obtained junction resistance may be affected by resistances of the first oxide layer 4021 and the second oxide layer 4022. In this embodiment, the first probe 11 and the second probe 12 are in contact with the first oxide layer 4021 of the first electrode 4011, and a part that is of the first oxide layer 4021 and that is located below or at a tip of the first probe 11 and the second probe 12 is electrically broken down. For example, the insertion depth of the second probe 12 is the thickness of the first oxide layer 4021, and a small part that is of the oxide layer and that is at the tip of the second probe 12 is broken down. In addition, the third probe 13 and the fourth probe 14 are in contact with the second oxide layer 4022 of the second electrode 4012, and a part that is of the second oxide layer 4022 and that is located below or at a tip of the third probe 13 and the fourth probe 14 is electrically broken down. For example, the insertion depth of the fourth probe 14 is the thickness of the second oxide layer 4022, and a small part that is of the oxide layer and that is at the tip of the fourth probe 14 is broken down. For example, the second probe 12 and the fourth probe 14 may be used for applying a constant current through the Josephson junction 41 and measuring a corresponding voltage, so that the junction resistance of the superconducting qubit may be determined based on the voltage and the constant current. In this embodiment, the probes exactly reach the surfaces of the first electrode and the second electrode, and the oxide layers are electrically broken down to further reduce interference, so that a detection result of the junction resistance can be more accurate.

In the measurement method of the junction resistance of the superconducting qubit according to this embodiment, the oxide layer that is on the first electrode 4011 and that is in contact with the first probe 11 and the second probe 12 is first electrically broken down, the oxide layer that is on the second electrode 4012 and that is in contact with the third probe 13 and the fourth probe 14 is electrically broken down, and the junction resistance is measured. In this way, impact of the oxide layers on resistance value measurement can be avoided, so that a resistance of the Josephson junction 41 may be obtained more accurately.

### Embodiment 8

In this embodiment, to save a quantity of probes, one of the probes may be further used as a shared probe, and the shared probe is moved to achieve a purpose of saving the probes. This embodiment may be further optimized based on Embodiment 5 to Embodiment 7.

For example, the step of electrically breaking down the second oxide layer 4022 may be as follows: enabling the first probe 11 and the third probe 13 to be in contact with the second oxide layer 4022 by moving the first probe 11; and forming a potential difference between the first probe 11 and the third probe 13, to electrically break down the second oxide layer 4022.

In this embodiment, a quantity of used probes may be reduced, and only the first probe 11, the second probe 12, and the third probe 13 need to be used for measuring the junction resistance.

Preferably, when one probe is on the surface of the first oxide layer, and the other probe is only inserted into or exactly penetrates through the oxide layer, the probe located on the surface of the first oxide layer is used as the shared probe.

For example, the first electrode and the second electrode may be one of the following elements formed on a substrate of the superconducting quantum chip: a capacitor electrode plate and a ground electrode plate.

For example, the first oxide layer and the second oxide layer 4022 are native oxide layers. For example, when the first electrode 4011 and the second electrode 4012 are made of aluminum (Al), the oxide layers are oxides of the aluminum (Al).

### Embodiment 9

This embodiment provides a measurement system of a junction resistance of a superconducting qubit. FIG. 12 is a schematic structural diagram of a measurement system of a junction resistance of a superconducting qubit according to this embodiment.

The following describes, with reference to the accompanying drawings, implementation details of the measurement system of the junction resistance of the superconducting qubit according to this embodiment. Refer to FIG. 11. The qubit includes a Josephson junction 41, and a first electrode 4011 and a second electrode 4012 that are separately connected to the Josephson junction 41.

As shown in FIG. 12, the measurement system of the junction resistance of the superconducting qubit includes:
a first probe unit, configured to be in contact with a first oxide layer 4021 formed on a surface of the first electrode 4011;
a second probe unit, configured to be in contact with a second oxide layer 4022 formed on a surface of the second electrode 4012; and
a test instrument unit 34, where the test instrument unit 34 is connected to the first probe unit and the second probe unit, to apply a voltage for implementing electrical breakdown, apply a test current through a broken-down first oxide layer 4021, the Josephson junction 41, and a broken-down second oxide layer 4022, and measure a voltage between the broken-down first oxide layer 4021 and the broken-down second oxide layer 4022.

In an implementation, the test instrument unit 34 may include a constant current source component that provides the test current and an instrument component that measures a current and a voltage.

In this embodiment, the first probe unit includes a first probe 11 and a second probe 12, and the first probe 11 or the second probe 12 is inserted into the first oxide layer 4021.

Possibly, an insertion depth is a thickness of the first oxide layer 4021.

In this embodiment, the second probe unit includes a third probe 13 and a fourth probe 14, and the third probe 13 or the fourth probe 14 is inserted into the second oxide layer 4022.

Possibly, an insertion depth is a thickness of the second oxide layer 4022.

In this embodiment, the first oxide layer 4021 is a native oxide layer formed on the surface of the first electrode 4011, and the second oxide layer 4022 is a native oxide layer formed on the surface of the second electrode 4012. In an implementation, a hardness of the first probe 11 is less than a hardness of the oxide layer, a hardness of the second probe 12 is greater than the hardness of the oxide layer and less than a hardness of the first electrode 4011, a hardness of the third probe 13 is less than a hardness of the oxide layer, and a hardness of the fourth probe 14 is greater than the hardness of the oxide layer and less than a hardness of the second electrode 4012. The first probe 11, the second probe 12, the third probe 13, and the fourth probe 14 are all tungsten needles.

In this embodiment, the first electrode 4011 and the second electrode 4012 are one of the following elements formed on a substrate of a superconducting quantum chip: a capacitor electrode plate and a ground electrode plate.

It should be noted herein that the foregoing measurement system of the junction resistance of the superconducting qubit has a beneficial effect similar to the foregoing embodiment of the measurement method of the junction resistance. Therefore, details are not described again. For technical details not disclosed in the embodiments of the measurement system of the junction resistance in the present application, a person skilled in the art may refer to the foregoing descriptions of the measurement method of the junction resistance for understanding. To save space, details are not described herein again.

In the measurement system of the junction resistance of the superconducting qubit according to this embodiment, the oxide layer that is on the first electrode 4011 and that is in contact with the first probe 11 and the second probe 12 is first electrically broken down, the oxide layer that is on the second electrode 4012 and that is in contact with the third probe 13 and the fourth probe 14 is electrically broken down, and the junction resistance is measured. In this way, impact of the oxide layers on resistance value measurement can be avoided, so that a resistance of the Josephson junction 41 may be obtained more accurately.

### Embodiment 10

To test a Josephson junction, an electrode of the Josephson junction needs to be electrically connected. An oxide layer is formed on a surface of the electrode of the Josephson junction. To form a good electrical connection with the electrode of the Josephson junction, a feasible solution is to use a probe to penetrate through the oxide layer to be in contact with the electrode. However, it is a very important step of how to enable the probe to form the good electrical connection with the electrode of the Josephson junction without damaging the Josephson junction.

Embodiment 10 of the present application provides an electrical contact connection method. According the method, that a probe exactly reaches a contacting surface of two film layers can be more accurately implemented, for example, a contacting surface of an electrode and an oxide layer.

Refer to FIG. 13. This embodiment includes the following content.

In this embodiment of the present application, the electrical contact connection method includes the following steps.

S1001: moving a probe toward a first film layer, and monitoring, in real time, a pressure exerted on the probe.

S1002: monitoring a first sudden change of the pressure, and continuing to move the probe.

S1003: monitoring a second sudden change of the pressure, and stopping movement of the probe when the second sudden change occurs, where the probe is in contact with a second film layer at this time.

In a specific implementation, the second film layer is an electrode of the Josephson junction, and the first film layer is an oxide layer on a surface of the electrode.

For example, the electrode may be made of a material such as aluminum or niobium. In addition, another superconducting material may also be used in the present application.

A thickness of the first film layer may range from 0.1 nm to 5 nm, for example, 0.3 nm, 0.5 nm, 0.8 nm, 1 nm, 1.2 nm, 1.5 nm, 1.7 nm, 2 nm, 2.3 nm, 2.6 nm, 2.9 nm, 3 nm, 3.1 nm, 3.4 nm, 3.6 nm, 3.8 nm, 4 nm, 4.3 nm, 4.5 nm, or 4.8 nm.

To reduce impact of an external environment, in this embodiment, the method may be performed in a dust-free chamber with a vibration isolation platform and a sound isolation box.

In S1001, in a normal case, the probe is initially not in contact with another external object. Therefore, a pressure is not exerted, and a monitoring result should be 0.

For example, in S1002, the first sudden change is that a pressure changes from 0 to 0.1-10 μN, denoted as a μN. When the first sudden change occurs, it means that the probe and the first film layer change from a non-contact state to a contact state.

Constraints of the first pressure sudden change include a probe shape, a material, a film layer thickness, and the like. Usually, a softer probe material indicates a blunter tip, a thicker film layer, and a greater pressure. Apparently, it may be understood that a hardness of the probe is at least greater than a hardness of the first film layer.

When the first sudden change occurs, the probe continues to move, that is, continues to be inserted deeper into the first film layer. In this process, a detected pressure usually increases continuously.

As the probe continues to be inserted deeper, when the second sudden change of the pressure occurs, it is considered that the probe exactly penetrates through the first film layer and is in contact with the second film layer.

For example, in S1003, the second sudden change is that a pressure becomes 10 to 100 times the pressure of the first sudden change.

A multiple of the second pressure sudden change may vary depending on an actual material and a thickness of an oxide layer. For example, for an aluminum film, a possible multiple is 10 to 12 times. However, for a niobium film, a possible multiple is 50 to 60 times.

For example, for the aluminum film, the first sudden change is that the pressure changes from 0 to 5 μN. As the probe continues to move, for example, the pressure becomes 6 μN, it may be considered that the probe is still in the first film layer. When the pressure becomes 50 μN (for example, a sudden change occurs from 6.2 μN), a changed pressure at this time is 10 times the pressure of the first sudden change, and it may be considered that the probe exactly penetrates through the first film layer and is in contact with the second film layer.

In this embodiment of the present application, a multiple of the second pressure sudden change may be a multiple that is obtained after a plurality of experiments and representations and that is suitable for related hardware and a to-be-measured component.

In S1003, when it is detected that the second sudden change of the pressure occurs, the probe immediately stops movement, to avoid continuing to be inserted into the second film layer.

It is verified by an experiment that the method in this embodiment can implement the electrical connection between the probe and the electrode. At this time, the probe only penetrates through the oxide layer, and does not damage the electrode, or the probe leaves only a very small pit on the surface of the electrode, and damage is extremely small (usually acceptable in this case), which hardly affects performance of the Josephson junction.

In addition, in this embodiment, the probe moves at a slow and constant speed. Because the oxide layer is relatively thin, a probe speed should not be relatively high. In addition, it is convenient to immediately stop moving the probe when a target position is reached.

For example, the probe moves at a speed of 10 nm/s to 1 μm/s.

The electrical contact connection method provided in this embodiment can enable the probe to exactly penetrate through the oxide layer and be in contact with the electrode as much as possible, and reduce damage to the electrode of the Josephson junction as much as possible.

### Embodiment 11

To test a Josephson junction, an electrode of the Josephson junction needs to be electrically connected. An oxide layer is formed on a surface of the electrode of the Josephson junction. To form a good electrical connection with the electrode of the Josephson junction, a feasible solution is to use a probe to penetrate through the oxide layer to be in contact with the electrode. However, it is a very important step of how to enable the probe to form the good electrical connection with the electrode of the Josephson junction without damaging the Josephson junction.

Embodiment 11 of the present application provides an electrical contact connection system. That a probe exactly reaches a boundary of two film layers can be implemented more accurately by using the system, for example, a boundary of an electrode and an oxide layer. Correspondingly, the electrical contact connection method in the present application can be implemented more conveniently by using the system.

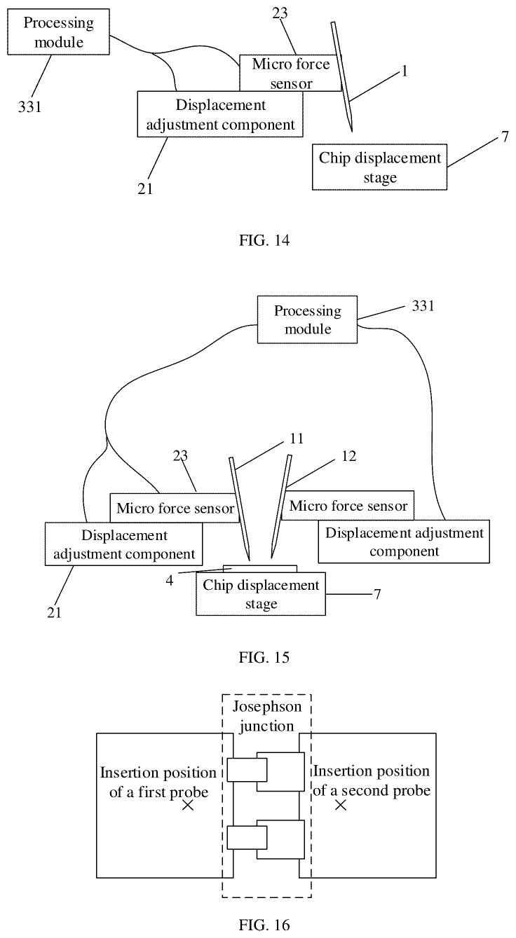

Refer to FIG. 14. The electrical contact connection system includes:
a displacement adjustment component 21, a micro force sensor 23 disposed on the displacement adjustment component 21, and a probe 1 disposed on the micro force sensor 23; and
a chip displacement stage 7, where the probe 1 can move relative to the chip displacement stage 7 when driven by the displacement adjustment component 21.

Possibly, the electrical contact connection system is further including a processing module 331. The processing module 331 receives, in real time, a pressure detected by the micro force sensor 23, and at least monitors a pressure value when a sudden change of the pressure occurs. The processing module 331 further controls movement of the displacement adjustment component 21 based on the pressure value monitored when the sudden change occurs.

The processing module 331 is configured to continuously monitor a pressure exerted when the probe 1 moves, and monitor a first sudden change of the pressure and a second sudden change of the pressure.

When monitoring the first sudden change of the pressure, the processing module 331 continues to enable the displacement adjustment component 21 to move the probe 1. When monitoring the second sudden change of the pressure, the processing module 331 immediately enables the displacement adjustment component 21 to stop moving the probe 1.

To make the method in the present application more accurate during pressure detection, in an embodiment, the probe 1 is disposed on a sensing head of the micro force sensor 23, and the probe 1 may be rigidly connected to the sensing head of the micro force sensor 23, so that force transfer is more direct.

The probe 1 is a tungsten needle or a tungsten alloy needle, a protective layer may be electroplated on a surface of the probe 1, and a tip diameter of the probe 1 ranges from 0.1 to 50 μm.

The chip displacement stage 7 is mainly configured to carry a to-be-measured component, for example, a to-be-measured superconducting quantum chip that has a Josephson junction.

### Embodiment 12

Embodiment 12 of the present application provides a probe apparatus. The apparatus can enable a probe to exactly penetrate through an oxide layer and be in contact with an electrode as much as possible, and reduce damage to an electrode of a Josephson junction as much as possible.

Refer to FIG. 15. This embodiment provides a probe apparatus. The probe apparatus is configured to measure a superconducting quantum chip, and includes a first probe 11, a second probe 12, a probe control mechanism, and a chip displacement stage 7.

The probe control mechanism is configured to: control the first probe 11 and the second probe 12 to be inserted downward opposite sides of a Josephson junction on a superconducting quantum chip 4, and enable the first probe 11 and the second probe 12 to exactly penetrate through oxide layers on surfaces of electrodes of the Josephson junction.

The chip displacement stage 7 is configured to carry the superconducting quantum chip 4.

For example, the probe control mechanism includes displacement adjustment components 21, and micro force sensors 23 fastened to the displacement adjustment components 21. The first probe 11 and the second probe 12 are respectively fastened to the corresponding micro force sensors 23, and each of the micro force sensors 23 is independently connected to the corresponding probe.

This embodiment may be implemented based on Embodiment 11. Specifically, a set of a displacement adjustment component 21, a micro force sensor 23 fastened to the displacement adjustment component 21, and the second probe 12 fastened to the micro force sensor 23 may be added based on Embodiment 11 for implementation.

In this way, with reference to FIG. 16, this embodiment can implement insertion on two sides of the Josephson junction, and achieve a purpose of exact insertion on the two sides.

### Embodiment 13

Embodiment 13 of the present application provides a measurement system of a junction resistance of a superconducting qubit. The system can enable a probe to exactly penetrate through an oxide layer and be in contact with an electrode as much as possible, reduce damage to an electrode of a Josephson junction as much as possible, and improve measurement accuracy.

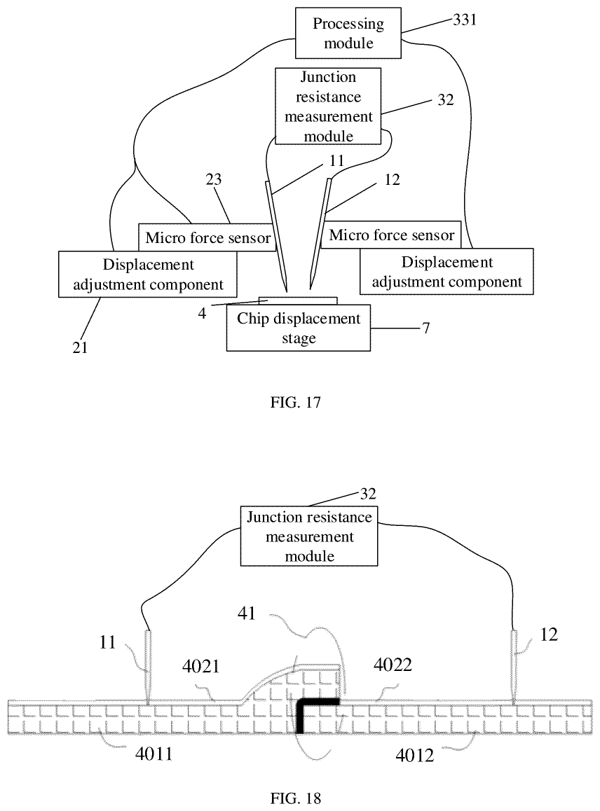

Refer to FIG. 17. This embodiment provides a measurement system of a junction resistance of a superconducting qubit, including:
a probe apparatus; and
a junction resistance measurement module 32, where the junction resistance measurement module 32 is separately connected to a first probe 11 and a second probe 12.

The probe apparatus may be the probe apparatus provided in Embodiment 12 of the present application, and is not repeatedly described herein. A corresponding technical effect thereof is also applicable to this embodiment.

The junction resistance measurement module 32 in this embodiment may be the test instrument unit (as described in Embodiment 9), or may be a module that only performs resistance measurement and that is in the test instrument unit.

Based on the measurement system of the junction resistance of the superconducting qubit in this embodiment, because the probe can be positioned as accurate as possible, precision of a measurement result of a resistance of the Josephson junction is relatively high.

### Embodiment 14

Embodiment 14 of the present application provides a measurement circuit of a junction resistance of a superconducting qubit. The measurement circuit can obtain relatively high measurement accuracy.

Refer to FIG. 18. A measurement circuit of a junction resistance of a superconducting qubit is provided. A Josephson junction 41 includes a first electrode 4011 and a second electrode 4012. The measurement circuit includes:
a first probe 11 electrically connected to the first electrode 4011, where a first oxide layer 4021 is formed on a surface of the first electrode 4011, and the first probe 11 exactly penetrates through the first oxide layer 4021 to form electrical contact with the first electrode 4011;
a second probe 12 electrically connected to the second electrode 4012, where a second oxide layer 4022 is formed on a surface of the second electrode 4012, and the second probe 12 exactly penetrates through the second oxide layer 4022 to form electrical contact with the second electrode 4012; and
a junction resistance measurement module 32 electrically connected to both the first probe 11 and the second probe 12, where the junction resistance measurement module 32 is configured to apply an electrical signal to the first probe 11 and the second probe 12 to measure a resistance of the Josephson junction.

In this embodiment, both the first probe 11 and the second probe exactly penetrate through the oxide layers and are in electrical contact with the electrodes. Therefore, detection accuracy may be effectively improved, and interference of the oxide layers to the junction resistance is reduced.

### Embodiment 15

Embodiment 15 of the present application provides a measurement method of a junction resistance of a superconducting qubit. The measurement method can obtain relatively high measurement accuracy.

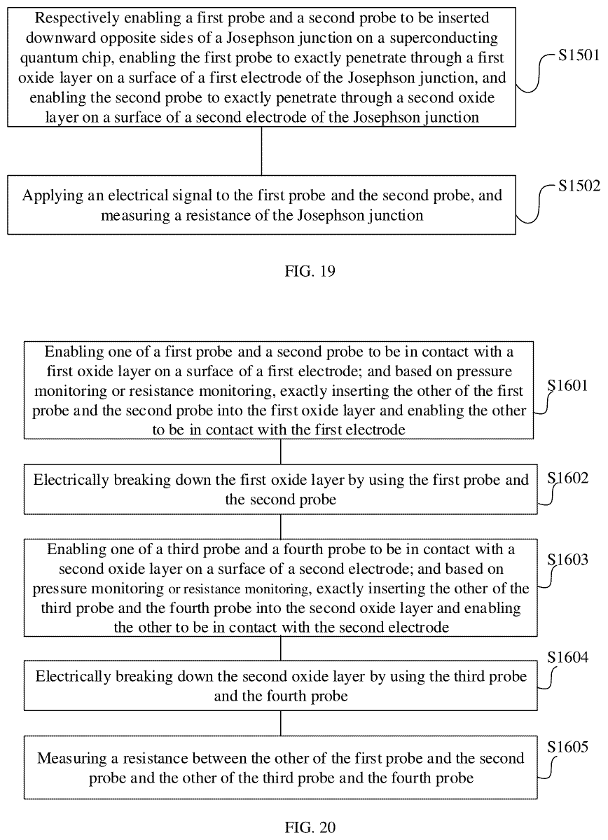

Refer to FIG. 19. This embodiment provides a measurement method of a junction resistance of a superconducting qubit, including the following steps.

S1501: respectively enabling a first probe and a second probe to be inserted downward opposite sides of a Josephson junction on a superconducting quantum chip, enabling the first probe to exactly penetrate through a first oxide layer on a surface of a first electrode of the Josephson junction, and enabling the second probe to exactly penetrate through a second oxide layer on a surface of a second electrode of the Josephson junction.

S1502: applying an electrical signal to the first probe and the second probe, and measuring a resistance of the Josephson junction.

Specifically, with reference to FIG. 17 and FIG. 18, in S1501, the step of enabling a first probe to be inserted downward a superconducting quantum chip and exactly penetrate a first oxide layer on a surface of a first electrode of the Josephson junction includes the following substeps.

Step 11: moving the first probe 11 toward the first oxide layer 4021 on the surface of the first electrode of the Josephson junction 41, and monitoring, in real time, a pressure exerted on the first probe 11.

Step 12: monitoring a first sudden change of the pressure, and continuing to move the first probe 11.

Step 13: monitoring a second sudden change of the pressure, and stopping movement of the first probe 11 when the second sudden change occurs, where the first probe 11 is in contact with the first electrode 4011 at this time.

In S1501, the step of enabling a second probe to be inserted downward a superconducting quantum chip and exactly penetrate a second oxide layer on a surface of a second electrode of the Josephson junction includes the following substeps.

Step 21: moving the second probe 12 toward the second oxide layer 4022 on the surface of the second electrode of the Josephson junction 41, and monitoring, in real time, a pressure exerted on the second probe 12.

Step 22: monitoring a first sudden change of the pressure, and continuing to move the second probe 12.

Step 23: monitoring a second sudden change of the pressure, and stopping movement of the second probe 12 when the second sudden change occurs, where the second probe is in contact with the second electrode 4012 at this time.

An operation process of Step 11 to Step 13 and that of Step 21 to Step 23 are basically the same, and may be performed in the manner described in Embodiment 10.

### Embodiment 16

Refer to FIG. 20. A sixteenth embodiment of the present application provides a measurement method of a junction resistance of a superconducting qubit. The method may be obtained through further optimization based on Embodiment 7 and Embodiment 10. The method includes the following steps.

S1601: enabling one of a first probe 11 and a second probe 12 to be in contact with a first oxide layer 4021 on a surface of a first electrode 4011; and based on pressure monitoring or resistance monitoring, exactly inserting the other of the first probe 11 and the second probe 12 into the first oxide layer 4021 and enabling the other to be in contact with the first electrode 4011.

S1602: electrically breaking down the first oxide layer 4021 by using the first probe 11 and the second probe 12.

S1603: enabling one of a third probe 13 and a fourth probe 14 to be in contact with a second oxide layer 4022 on a surface of a second electrode 4012; and based on pressure monitoring or resistance monitoring, exactly inserting the other of the third probe 13 and the fourth probe 14 into the second oxide layer 4022 and enabling the other to be in contact with the second electrode 4012.

S1604: electrically breaking down the second oxide layer 4022 by using the third probe 13 and the fourth probe 14.

S1605: measuring a resistance between the other of the first probe 11 and the second probe 12 and the other of the third probe 13 and the fourth probe 14.

In S1601 to S1604, the probe is in contact with the oxide layer on the surface of the electrode. That is, the probe is in contact with a surface that is of the oxide layer and that is away from the electrode. To be specific, a depth of which the probe is inserted into the oxide layer is 0. In other words, the probe is not inserted into the oxide layer.

In S1603 and S1604, for a process based on pressure monitoring, refer to the solution described in Embodiment 10. A corresponding technical effect thereof is also applicable to this embodiment.

In S1603 and S1604, for a process based on resistance value monitoring, refer to the solution described in Embodiment 19. A corresponding technical effect thereof is also applicable to this embodiment.

In the measurement method of the junction resistance of the superconducting qubit according to this embodiment, based on pressure monitoring or resistance value monitoring, the probe is positioned more accurately; and based on electrical breakdown of the oxide layer, interference of the oxide layer to the junction resistance may be better reduced. In this way, the junction resistance is more accurately measured. In addition, based on pressure monitoring, the probe reaches a contacting surface of the oxide layer and the electrode, and damage to the electrode can be reduced as much as possible.

### Embodiment 17

In this embodiment, to save a quantity of probes, one of the probes may be further used as a shared probe, and the shared probe is moved to achieve a purpose of saving the probes. This embodiment may be further optimized based on Embodiment 16. For the shared probe, refer to the solution described in Embodiment 8. Details are not described herein.

### Embodiment 18

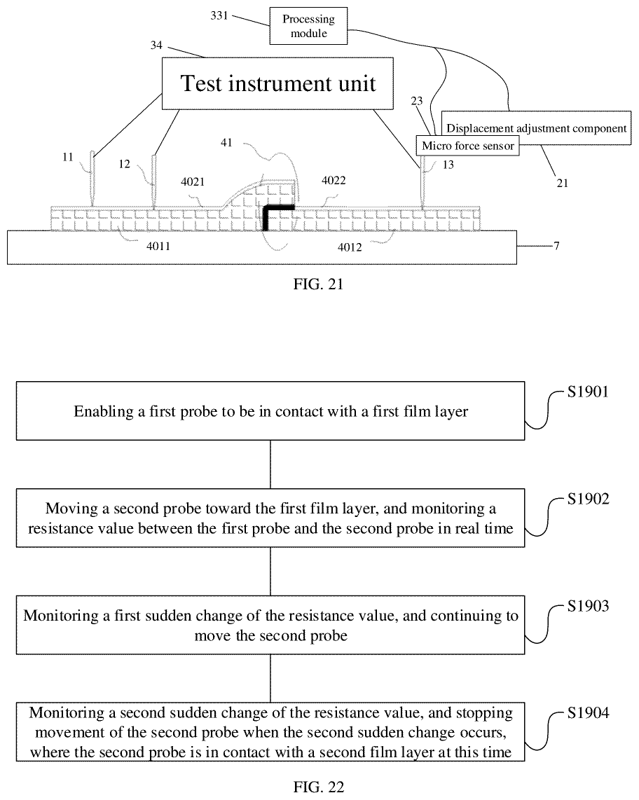

This embodiment provides a measurement system of a junction resistance of a superconducting qubit. FIG. 21 is a schematic structural diagram of a measurement system of a junction resistance of a superconducting qubit according to this embodiment.

Refer to FIG. 21. The qubit includes a Josephson junction 41, the Josephson junction 41 includes a first electrode 4011 and a second electrode 4012, a first oxide layer 4021 is formed on the first electrode 4011, and a second oxide layer 4022 is formed on the second electrode 4012.

The measurement system of the junction resistance of the superconducting qubit includes:
an electrical contact connection system, including a first probe 11, a second probe 12, and a third probe 13, where the first probe 11 is configured to cooperate with the second probe 12 and/or the third probe 13; and the electrical contact connection system is: configured to enable the second probe 12 to be inserted into the first oxide layer 4021, where an insertion depth is a thickness of the first oxide layer 4021; and further configured to enable the third probe 13 to be inserted into the second oxide layer 4022, where an insertion depth is a thickness of the second oxide layer 4022; and

a test instrument unit 34, where the test instrument unit 34 is connected to the first probe 11, the second probe 12, and the third probe 13, to apply a voltage for implementing electrical breakdown, apply a test current through a broken-down first oxide layer 4021, the Josephson junction 41, and a broken-down second oxide layer 4022, and measure a voltage between the broken-down first oxide layer 4021 and the broken-down second oxide layer 4022.

In an implementation, the test instrument unit 34 may include a constant current source component that provides the test current and an instrument component that measures a current and a voltage.

The electrical contact connection system can more accurately implement that the probe exactly reaches a contacting surface of the electrode and the oxide layer.

Refer to FIG. 21. The electrical contact connection system further includes:
a displacement adjustment component 21, a micro force sensor 23 disposed on the displacement adjustment component 21, and a probe disposed on the micro force sensor 23, where the displacement adjustment component 21 and the micro force sensor 23 are shown only on the third probe 13; and it should be understood that each probe may be as least fastened to a displacement adjustment component 21, at least some probes may be fastened to micro force sensors 23, some probes are independent of each other, and the micro force sensors 23 fastened to the probes are independent of each other; and
a chip displacement stage 7, where the first probe 11, the second probe 12, and the third probe 13 can move relative to the chip displacement stage 7 when driven by the displacement adjustment component 21.

Possibly, the electrical contact connection system further includes a processing module 331. The processing module 331 receives, in real time, a pressure detected by the micro force sensor 23, and at least monitors a pressure value when a sudden change of the pressure occurs. The processing module 331 further controls movement of the displacement adjustment component 21 based on the pressure value monitored when the sudden change occurs.

The processing module 331 is configured to continuously monitor a pressure exerted when the probe moves, and monitor a first sudden change of the pressure and a second sudden change of the pressure.

For a pressure monitoring method, and an operation process corresponding to the pressure sudden change, refer to the solution in Embodiment 10. A corresponding technical effect thereof is also applicable to this embodiment.

To make the method in the present application more accurate during pressure detection, in an implementation, the probe is disposed on a sensing head of the micro force sensor 23, and the probe may be rigidly connected to the sensing head of the micro force sensor 23, so that force transfer is more direct.

The probes are tungsten needles or tungsten alloy needles, protective layers may be electroplated on a surface of the probes, and tip diameters of the probes range from 0.1 to 50 μm.

The chip displacement stage 7 is mainly configured to carry a to-be-measured component, for example, a to-be-measured superconducting quantum chip that has a Josephson junction.

The first probe 11 may move on two sides of the Josephson junction 41. For example, the first probe 11 can cooperate with the second probe 12 on one side to break down the first oxide layer 4021 on the side, or the first probe 11 can cooperate with the third probe 13 on the other side to break down the second oxide layer 4022 on the other side. In this way, a quantity of probes can be reduced, and complexity of the entire system can be reduced.

It should be understood that this embodiment may further include a fourth probe. In this way, for example, the fourth probe is configured to cooperate with the third probe 13, and the first probe 11 is configured to cooperate with the second probe 12.

In the measurement system of the junction resistance of the superconducting qubit according to this embodiment, based on pressure monitoring, the probe is positioned more accurately; and based on electrical breakdown of the oxide layer, interference of the oxide layer to the junction resistance may be better reduced. In this way, the junction resistance is more accurately measured. In addition, based on pressure monitoring, the probe reaches a contacting surface of the oxide layer and the electrode, and damage to the electrode can be reduced as much as possible.

### Embodiment 19

To test a Josephson junction, an electrode of the Josephson junction needs to be electrically connected. An oxide layer is formed on a surface of the electrode of the Josephson junction. To form a good electrical connection with the electrode of the Josephson junction, a feasible solution is to use a probe to penetrate through the oxide layer to be in contact with the electrode. However, it is a very important step of how to enable the probe to form the good electrical connection with the electrode of the Josephson junction without damaging the Josephson junction.

In view of this, in this embodiment, an electrical contact connection method is proposed in a targeted manner. This method can enable the probe to exactly penetrate through the oxide layer and be in contact with the electrode as much as possible, and reduce damage to the electrode of the Josephson junction as much as possible.

In this embodiment, with reference to FIG. 22, the electrical contact connection method includes the following steps.

S1901: enabling a first probe to be in contact with a first film layer.

S1902: moving a second probe toward the first film layer, and monitoring a resistance value between the first probe and the second probe in real time.

S1903: monitoring a first sudden change of the resistance value, and continuing to move the second probe.

S1904: monitoring a second sudden change of the resistance value, and stopping movement of the second probe when the second sudden change occurs, where the second probe is in contact with a second film layer at this time.

In S1901, the enabling a first probe to be in contact with a first film layer may include the following several cases: being in contact with a surface of the first film layer, being inserted into the first film layer, and exactly penetrating through the first film layer.

In a specific implementation, the second film layer is an electrode of the Josephson junction, and the first film layer is an oxide layer of the electrode.

For example, the electrode may be made of a material such as aluminum or niobium. In addition, another superconducting material may also be used in the present application.

A thickness of the first film layer may range from 0.1 nm to 5 nm, for example, 0.3 nm, 0.5 nm, 0.8 nm, 1 nm, 1.2 nm, 1.5 nm, 1.7 nm, 2 nm, 2.3 nm, 2.6 nm, 2.9 nm, 3 nm, 3.1 nm, 3.4 nm, 3.6 nm, 3.8 nm, 4 nm, 4.3 nm, 4.5 nm, or 4.8 nm.

To reduce impact of an external environment, in this embodiment, the method may be performed in a dust-free chamber with a vibration isolation platform and a sound isolation box.

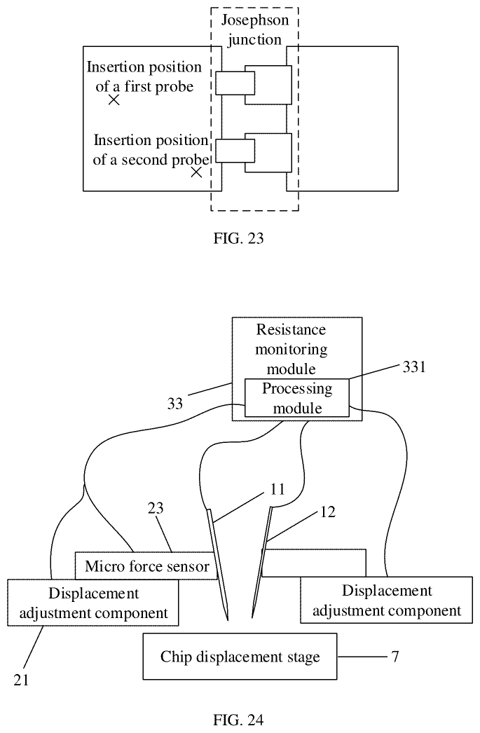

In a preferred option, as shown in FIG. 23, an insertion position of the first probe is farther away from the Josephson junction than an insertion position of the second probe. For example, the insertion position of the first probe is 20-200 μm away from a junction area. Therefore, the insertion position of the first probe is away from the junction area, and impact on the junction may be ignored.

In addition, a relatively thick probe may be selected as the first probe, and may be easily inserted into or penetrate through the oxide layer on the surface of the electrode.

In an embodiment, in S1901, a pressure exerted on the first probe is monitored, so that the first probe is in contact with the first film layer.

For example, the first probe may be in contact with the first film layer in the manner described in Embodiment 10.

In S1902, when the second probe is just started, because the second probe is not yet in contact with the first film layer, the resistance value between the first probe and the second probe tends to be infinity (10 MΩ or more).

For example, in S1903, the first sudden change is that a resistance value is reduced to 10 KΩ-10 MΩ. When the first sudden change occurs, it means that the second probe and the first film layer change from a non-contact state to a contact state.

Constraints of the first sudden change include a probe material, a film layer material, and the like.

When the first sudden change occurs, the second probe continues to move, that is, continues to be inserted deeper into the first film layer. In this process, the resistance value usually decreases continuously.

As the second probe continues to be inserted deeper, when the second sudden change of the resistance value occurs, it is considered that the second probe exactly penetrates through the first film layer and is in contact with the second film layer.

For example, in S1904, the second sudden change is that a resistance value changes to 100-1000 Ω, for example, 40-150 Ω.

In S1904, when it is detected that the second sudden change of the resistance value occurs, the second probe immediately stops movement, to avoid continuing to be inserted into the second film layer.

It is verified by an experiment that the method in this embodiment can implement the electrical connection between the second probe and the electrode. At this time, the second probe only penetrates through the oxide layer, and does not damage the electrode, or the probe leaves only a very small pit on the surface of the electrode, and damage is extremely small, which hardly affects performance of the Josephson junction.

In addition, in this embodiment, the second probe moves at a slow and constant speed. Because the oxide layer is relatively thin, a probe speed should not be relatively high. In addition, it is convenient to immediately stop moving the probe when a target position is reached.

For example, the second probe moves at a speed of 10 nm/s to 1 μm/s.

The electrical contact connection method provided in this embodiment can enable the probe to exactly penetrate through the oxide layer and be in contact with the electrode as much as possible, and reduce damage to the electrode of the Josephson junction as much as possible.

### Embodiment 20

To test a Josephson junction, an electrode of the Josephson junction needs to be electrically connected. An oxide layer is formed on a surface of the electrode of the Josephson junction. To form a good electrical connection with the electrode of the Josephson junction, a feasible solution is to use a probe to penetrate through the oxide layer to be in contact with the electrode. However, it is a very important step of how to enable the probe to form the good electrical connection with the electrode of the Josephson junction without damaging the Josephson junction.

Embodiment 20 of the present application provides an electrical contact connection system. That a probe exactly reaches a contacting surface of two film layers can be more accurately implemented by using the system, for example, a contacting surface of an electrode and an oxide layer. Correspondingly, the method of the present application can be more accurately implemented by using the system.

Refer to FIG. 24. The electrical contact connection system includes:
displacement adjustment components 21, and a first probe 11 and a second probe 12 that are disposed on the displacement adjustment components 21;
a resistance monitoring module 33, where both the first probe 11 and the second probe 12 are connected to the resistance monitoring module 33; and
a chip displacement stage 7, where the first probe 11 and the second probe 12 can separately move relative to the chip displacement stage 7 when driven by the displacement adjustment components 21.

Possibly, the resistance monitoring module 33 is configured to: monitor, in real time, a detected resistance value, and control movement of the displacement adjustment components 21 when a sudden change of the resistance value occurs.

Possibly, the electrical contact connection system further includes a micro force sensor 23. To make the method in the present application more accurate during pressure detection, in an embodiment, the first probe 11 is disposed on a sensing head of the micro force sensor 23, and the first probe 11 may be rigidly connected to the sensing head of the micro force sensor 23, so that force transfer is more direct.

Possibly, the electrical contact connection system further includes a processing module 331. The processing module 331 receives, in real time, a pressure detected by the micro force sensor 23, and at least records a pressure value when a sudden change of the pressure occurs. The processing module 331 further controls movement of the displacement adjustment component 21 based on the pressure value recorded when the sudden change occurs.

The processing module 331 is configured to continuously monitor a pressure exerted when the first probe 11 moves, and monitor a first sudden change of the pressure and a second sudden change of the pressure.

For example, when monitoring the first sudden change of the pressure, the processing module 331: immediately enables the displacement adjustment component 21 to stop moving the first probe 11; or continues to enable the displacement adjustment component 21 to move the first probe 11, and stop moving the first probe 11 at any time as required. When monitoring the second sudden change of the pressure, the processing module 331 immediately enables the displacement adjustment component 21 to stop moving the first probe 11.

The processing module 331 may be integrated into the resistance monitoring module 33. To be specific, the processing module 331 may not only control movement of the displacement adjustment component 21 based on a pressure signal, but also control movement of the displacement adjustment component 21 based on a resistance signal.

The first probe 11 and the second probe 12 are tungsten needles or tungsten alloy needles, protective layers may be electroplated on surfaces of the first probe 11 and the second probe 12, and the first probe 11 is thicker than the second probe 12.

For example, a shaft diameter of the first probe 11 ranges from 10 to 500 μm and a tip diameter ranges from 0.5 to 15 μm, and a shaft diameter of the second probe 12 ranges from 5 to 50 μm and a tip diameter ranges from 0.2 to 1 μm.

The first probe 11 is relatively thick to easily penetrate through the oxide layer of the electrode of the Josephson junction. The second probe 12 is relatively thin to reduce damage to the electrode as much as possible, so that impact on the junction may be ignored.

The chip displacement stage 7 is mainly configured to carry a to-be-measured component, for example, a superconducting quantum chip that has a Josephson junction.

### Embodiment 21

Embodiment 21 of the present application provides a probe apparatus. The apparatus can enable a probe to exactly penetrate through an oxide layer and be in contact with an electrode as much as possible, and reduce damage to an electrode of a Josephson junction as much as possible.

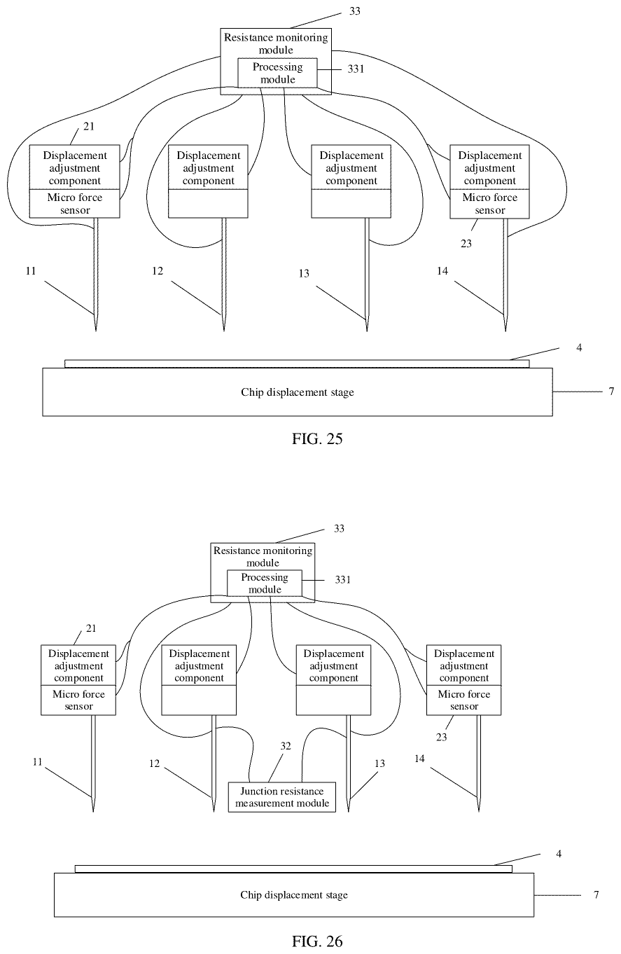

In an embodiment, with reference to FIG. 25, a probe apparatus is provided. The probe apparatus is configured to measure a superconducting quantum chip, and includes a first probe 11, a second probe 12, a third probe 13, a probe control mechanism, a resistance monitoring module 33, and a chip displacement stage 7.

The probe control mechanism is configured to control the first probe 11 to be inserted downward at least one side of the Josephson junction on the superconducting quantum chip 4, and enable the first probe 11 to be in contact with an oxide layer on a surface of an electrode of the Josephson junction. The probe control mechanism is further configured to control the second probe 12 and the third probe 13 to be respectively inserted downward two sides of the Josephson junction on the superconducting quantum chip, and enable the second probe 12 and the third probe 13 to exactly penetrate through oxide layers on surfaces of electrodes of the Josephson junction.

The first probe 11, the second probe 12, and the third probe 13 are all connected to the resistance monitoring module 33, to obtain a resistance value between the first probe 11 and the second probe 12, and a resistance value between the first probe 11 and the third probe 13.

The chip displacement stage 7 is configured to carry the superconducting quantum chip 4.

Possibly, the probe apparatus further includes a fourth probe 14. The probe control mechanism is further configured to control the fourth probe 14 to be inserted downward one side that is of the Josephson junction on the superconducting quantum chip 4 and that is not inserted downward by the first probe 11, and enable the fourth probe 14 to be in contact with an oxide layer on a surface of an electrode of the Josephson junction. The fourth probe 14 is connected to the resistance monitoring module 33.

For example, shaft diameters of the first probe 11 and the fourth probe 14 range from 10 to 500 μm and tip diameters range from 0.5 to 15 μm, and shaft diameters of the second probe 12 and the third probe 13 range from 5 to 50 μm and tip diameters range from 0.2 to 1 μm.

In an implementation, the probe control mechanism includes displacement adjustment components 21, and micro force sensors 23 fastened to the displacement adjustment components 21, the first probe 11 and the fourth probe 14 are respectively fastened to one of the micro force sensors 23, and the second probe 12 and the third probe 13 are fastened to the displacement adjustment components 21.

Possibly, the probe apparatus further includes a processing module 331. The processing module 331 receives, in real time, a pressure detected by the micro force sensor 23, and at least monitors a pressure value when a sudden change of the pressure occurs. The processing module 331 further controls movement of the chip displacement stage based on the pressure value monitored when the sudden change occurs.

### Embodiment 22

Embodiment 22 of the present application provides a measurement system of a junction resistance of a superconducting qubit. The system can enable a probe to exactly penetrate through an oxide layer and be in contact with an electrode as much as possible, reduce damage to an electrode of a Josephson junction as much as possible, and improve measurement accuracy.

Refer to FIG. 26. This embodiment provides a measurement system of a junction resistance of a superconducting qubit, including:
a probe apparatus; and
a junction resistance measurement module 32, where the junction resistance measurement module 32 is connected to a second probe 12 and a third probe 13.

The probe apparatus may be the probe apparatus provided in Embodiment 21 of the present application, and is not repeatedly described herein. A corresponding technical effect thereof is also applicable to this embodiment.

Possibly, in this embodiment, the junction resistance measurement module 32 may be replaced with a test instrument unit 34, so that an oxide layer may also be broken down in this embodiment.

Based on the measurement system of the junction resistance of the superconducting qubit in this embodiment, because the probe can be positioned as accurate as possible, precision of a measurement result of a resistance of the Josephson junction is relatively high.

### Embodiment 23

Embodiment 23 of the present application provides a measurement method of a junction resistance of a superconducting qubit. The measurement method can obtain relatively high measurement accuracy.

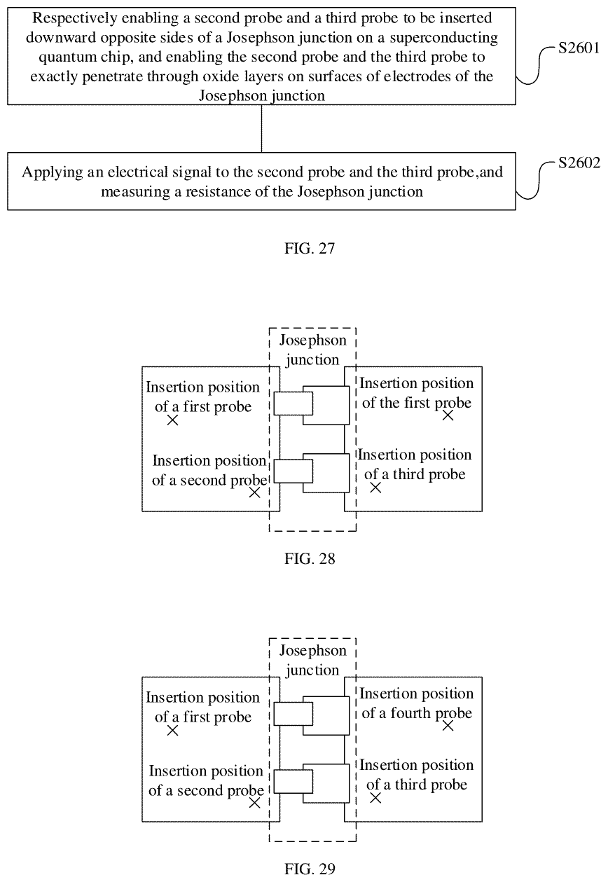

Refer to FIG. 26 and FIG. 27. This embodiment provides a measurement method of a junction resistance of a superconducting qubit, including the following steps.

S2601: respectively enabling a second probe 12 and a third probe 13 to be inserted downward opposite sides of a Josephson junction on a superconducting quantum chip 4, and enabling the second probe 12 and the third probe 13 to exactly penetrate through oxide layers on surfaces of electrodes of the Josephson junction.

S2602: applying an electrical signal to the second probe 12 and the third probe 13, and measuring a resistance of the Josephson junction.

Specifically, in S2601, the step of enabling a second probe 12 to be inserted downward a superconducting quantum chip 4 and exactly penetrate through an oxide layer on a surface of an electrode of the Josephson junction includes the following substeps.

Step 11: enabling a first probe 11 to be in contact with a first oxide layer on one side of the Josephson junction.

Step 12: moving the second probe 12 toward the first oxide layer on one side of the Josephson junction, and monitoring a resistance value between the first probe and the second probe 12 in real time.

Step 13: monitoring a first sudden change of the resistance value, and continuing to move the second probe 12.

Step 14: monitoring a second sudden change of the resistance value, and stopping movement of the second probe 12 when the second sudden change occurs, where the second probe 12 is in contact with a first electrode of the Josephson junction at this time.

An insertion position of the first probe 11 is farther away from the Josephson junction than an insertion position of the second probe 12. FIG. 23 shows a relative position when the first probe and the second probe are used for insertion.

Specifically, in S2601, the step of enabling a third probe 13 to be inserted downward a superconducting quantum chip and exactly penetrate through an oxide layer on a surface of an electrode of the Josephson junction includes the following substeps.

Step 21: enabling the first probe 11 or a fourth probe 14 to be in contact with a second oxide layer on the other side of the Josephson junction.

Step 22: moving the third probe 13 toward the second oxide layer on the other side of the Josephson junction, and monitoring a resistance value between the first probe 11 or the fourth probe 14 and the third probe 13 in real time.

Step 23: monitoring a first sudden change of the resistance value, and continuing to move the third probe 13.

Step 24: monitoring a second sudden change of the resistance value, and stopping movement of the third probe 13 when the second sudden change occurs, where the third probe 13 is in contact with a second electrode of the Josephson junction at this time.

An insertion position of the first probe or the fourth probe is farther away from the Josephson junction than an insertion position of the third probe. FIG. 28 shows a relative position when the first probe and the third probe are used for insertion. FIG. 29 shows a relative position when the third probe and the fourth probe are used for insertion.

An operation process of Step 11 to Step 14 and that of Step 21 to Step 24 are basically the same, and may be performed in the manner described in Embodiment 19.

This embodiment provides a simple and accurate resistance measurement method. In a measurement process, a change of a resistance between probes is monitored in real time, so that a probe can be precisely inserted downward a contacting surface of an oxide layer of an electrode of a Josephson junction and the electrode, and the probe can form a good electrical connection with the electrode of the Josephson junction without damaging the electrode. On this basis, a resistance of the Josephson junction is measured, and measurement accuracy may be effectively improved.

In the descriptions of this specification, descriptions with reference to the terms “an embodiment”, “some embodiments”, “an example”, “a specific example”, or the like mean that specific features, structures, materials, or characteristics described in combination with the embodiments or examples are included in at least one embodiment or example of the present application. In this specification, the schematic representation of the foregoing terms does not necessarily refer to a same embodiment or example. Moreover, the described specific features, structures, materials, or characteristics may be combined in any one or more embodiments in an appropriate manner. In addition, different embodiments or examples described in this specification may be combined and grouped by those skilled in the art.

The foregoing are merely preferred embodiments of the present application, and have no limitation to the present application. Any variation, such as equivalent replacement or modification, made by a person skilled in the art to the technical solutions and technical content disclosed in the present application without departing from the scope of the technical solutions of the present application shall belong to content of the technical solutions of the present application and still belong to the protection scope of the present application.

What is claimed is:

1. A measurement method of a junction resistance of a superconducting qubit, wherein the superconducting qubit comprises a Josephson junction, the Josephson junction comprises a first electrode and a second electrode, and the measurement method comprises:
electrically breaking down a first oxide layer formed on a surface of the first electrode;
electrically breaking down a second oxide layer formed on a surface of the second electrode;
applying a test current through a broken-down first oxide layer, the Josephson junction, and a broken-down second oxide layer, and measuring a voltage between the broken-down first oxide layer and the broken-down second oxide layer; and
determining the junction resistance of the superconducting qubit based on the voltage and the test current.

2. The method according to claim 1, wherein the electrically breaking down a first oxide layer formed on a surface of the first electrode comprises:
connecting a first probe and a second probe to the first oxide layer; and
forming a potential difference between the first probe and the second probe by applying a first breakdown voltage, to break down the first oxide layer.

3. The method according to claim 2, wherein the electrically breaking down a second oxide layer formed on a surface of the second electrode comprises:
connecting a third probe and a fourth probe to the second oxide layer; and
forming a potential difference between the third probe and the fourth probe by applying a second breakdown voltage, to break down the second oxide layer.

4. The method according to claim 3, wherein at the same time when the potential difference is formed between the first probe and the second probe by applying the first breakdown voltage, to break down the first oxide layer, the method further comprises:
applying a first protection voltage to the second electrode; and
wherein at the same time when the potential difference is formed between the third probe and the fourth probe by applying the second breakdown voltage, to break down the second oxide layer, the method further comprises:
applying a second protection voltage to the first electrode.

5. The method according to claim 4, wherein a potential difference between the first protection voltage and the first breakdown voltage is less than a barrier voltage of a barrier layer of the Josephson junction; and
a potential difference between the second protection voltage and the second breakdown voltage is less than the barrier voltage of the barrier layer of the Josephson junction.

6. The method according to claim 3, wherein the connecting a first probe and a second probe to the first oxide layer comprises: inserting the first probe and the second probe into the first oxide layer, wherein an insertion depth is less than a thickness of the first oxide layer; and
the connecting a third probe and a fourth probe to the second oxide layer comprises: inserting the third probe and the fourth probe into the second oxide layer, wherein an insertion depth is less than a thickness of the second oxide layer.

7. The method according to claim 3, wherein the connecting a first probe and a second probe to the first oxide layer comprises: inserting one of the first probe and the second probe into the first oxide layer, and enabling the other of the first probe and the second probe to be in contact with a surface that is of the first oxide layer and that is away from the first electrode; and
the connecting a third probe and a fourth probe to the second oxide layer comprises: inserting one of the third probe and the fourth probe into the second oxide layer, and enabling the other of the third probe and the fourth probe to be in contact with a surface that is of the second oxide layer and that is away from the second electrode.

8. The method according to claim 7, wherein an insertion depth of the one of the first probe and the second probe is a thickness of the first oxide layer; and
an insertion depth of the one of the third probe and the fourth probe is a thickness of the second oxide layer.

9. The method according to claim 7, wherein a material hardness of the probe inserted into the first oxide layer is greater than a hardness of the first oxide layer; and
a material hardness of the probe inserted into the second oxide layer is greater than a hardness of the second oxide layer.

10. The method according to claim 7, wherein a material hardness of the probe in contact with the surface that is of the first oxide layer and that is away from the first electrode is less than a hardness of the first oxide layer; and
a material hardness of the probe in contact with the surface that is of the second oxide layer and that is away from the second electrode is less than a hardness of the second oxide layer.

11. The method according to claim 2, wherein the electrically breaking down a second oxide layer formed on a surface of the second electrode comprises:
moving the first probe to connect the first probe and a third probe to the second oxide layer; and
forming a potential difference between the first probe and the third probe to break down the second oxide layer.

12. The method according to claim 1, wherein the electrically breaking down a first oxide layer formed on a surface of the first electrode comprises:
enabling one of a first probe and a second probe to be in contact with a surface that is of the first oxide layer and that is away from the first electrode; and based on pressure monitoring or resistance monitoring, inserting the other of the first probe and the second probe into the first oxide layer and enabling the other to be in contact with the first electrode; and
forming a potential difference between the first probe and the second probe by applying a first breakdown voltage, to break down the first oxide layer; and
wherein the electrically breaking down a second oxide layer formed on a surface of the second electrode comprises:
enabling one of a third probe and a fourth probe to be in contact with a surface that is of the second oxide layer and that is away from the second electrode; and based on pressure monitoring or resistance monitoring, inserting the other of the third probe and the fourth probe into the second oxide layer and enabling the other to be in contact with the second electrode; and
forming a potential difference between the third probe and the fourth probe by applying a second breakdown voltage, to break down the second oxide layer.

13. The method according to claim 12, wherein the based on pressure monitoring, inserting the other of the first probe and the second probe into the first oxide layer and enabling the other to be in contact with the first electrode comprises:
moving the other of the first probe and the second probe toward the first oxide layer on the surface of the first electrode, and monitoring, in real time, a pressure exerted on the other of the first probe and the second probe;
monitoring a first sudden change of the pressure, and continuing to move the other of the first probe and the second probe; and
monitoring a second sudden change of the pressure, and stopping movement of the other of the first probe and the second probe when the second mutation occurs, wherein the other of the first probe and the second probe is in contact with and electrically connected to the surface of the first electrode at this time; and
wherein the based on pressure monitoring, inserting the other of the third probe and the fourth probe into the second oxide layer and enabling the other to be in contact with the second electrode comprises:
moving the other of the third probe and the fourth probe toward the second oxide layer on the surface of the second electrode, and monitoring, in real time, a pressure exerted on the other of the third probe and the fourth probe;
monitoring a first sudden change of the pressure, and continuing to move the other of the third probe and the fourth probe; and
monitoring a second sudden change of the pressure, and stopping movement of the other of the third probe and the fourth probe when the second mutation occurs, wherein the other of the third probe and the fourth probe is in contact with and electrically connected to the surface of the second electrode at this time.

14. The method according to claim 13, wherein the first sudden change is that a pressure changes from 0 to 0.1-10 μN, and a pressure of the second sudden change is 10 to 100 times the pressure of the first sudden change; both a moving speed of the other of the first probe and the second probe and a moving speed of the other of the third probe and the fourth probe range from 10 nm/s to 1 μm/s; and both the thickness of the first oxide layer and the thickness of the second oxide layer range from 0.1 nm to 5 nm.

15. The method according to claim 12, wherein the based on resistance monitoring, inserting the other of the first probe and the second probe into the first oxide layer and enabling the other to be in contact with the first electrode comprises:
moving the other that is of the first probe and the second probe and that serves as a first auxiliary probe toward the first oxide layer, and monitoring a resistance value between the first probe and the second probe in real time;
monitoring a first sudden change of the resistance value, and continuing to move the first auxiliary probe; and
monitoring a second sudden change of the resistance value, and stopping movement of the first auxiliary probe when the second sudden change occurs, wherein the first auxiliary probe is in contact with and electrically connected to the surface of the first electrode of the Josephson junction at this time; and
wherein the based on resistance monitoring, inserting the other of the third probe and the fourth probe into the second oxide layer and enabling the other to be in contact with the second electrode comprises:
moving the other that is of the third probe and the fourth probe and that serves as a second auxiliary probe toward the second oxide layer, and monitoring a resistance value between the third probe and the fourth probe in real time;
monitoring a first sudden change of the resistance value, and continuing to move the second auxiliary probe; and
monitoring a second sudden change of the resistance value, and stopping movement of the second auxiliary probe when the second sudden change occurs, wherein the second auxiliary probe is in contact with and electrically connected to the surface of the second electrode of the Josephson junction at this time.

16. The method according to claim 15, wherein a distance between a contact position of the one of the first probe and the second probe and the Josephson junction is greater than a distance between an insertion position of the first auxiliary probe and the Josephson junction; and a distance between a contact position of the one of the third probe and the fourth probe and the Josephson junction is greater than a distance between an insertion position of the second auxiliary probe and the Josephson junction.

17. The method according to claim 16, wherein the first sudden change is that a resistance value decreases from 1 MΩ or more to 1-10 KΩ; the second sudden change is that a resistance value changes to 100-1000 Ω; and both the thickness of the first oxide layer and the thickness of the second oxide layer range from 0.1 nm to 5 nm.

18. A measurement system of a junction resistance of a superconducting qubit, wherein the superconducting qubit comprises a Josephson junction, the Josephson junction comprises a first electrode and a second electrode, and the measurement system comprises:
a first probe unit, configured to break down a first oxide layer formed on a surface of the first electrode;
a second probe unit, configured to break down a second oxide layer formed on a surface of the second electrode; and
a test instrument unit, wherein the test instrument unit is connected to the first probe unit and the second probe unit, to apply a voltage for implementing electrical breakdown, apply a test current through a broken-down first oxide layer, the Josephson junction, and a broken-down second oxide layer, and measure a voltage between the broken-down first oxide layer and the broken-down second oxide layer.
